(19) United States
(12) Patent Application Publication
(10) Pub. No.: US 2024/0145643 A1
(43) Pub. Date: May 2, 2024

(54) DISPLAY DEVICE AND MANUFACTURING METHOD THEREOF

(71) Applicant: Samsung Display Co., Ltd., Yongin-si (KR)

(72) Inventors: Jin Taek KIM, Yongin-si (KR); Ki Nyeng KANG, Yongin-si (KR); Veidhes BASRUR, Yongin-si (KR); Ock Soo SON, Yongin-si (KR); Yong Tae CHO, Yongin-si (KR)

(21) Appl. No.: 18/494,692

(22) Filed: Oct. 25, 2023

(30) Foreign Application Priority Data
Nov. 1, 2022 (KR) 10-2022-0143986

(51) Int. Cl. H01L 33/50; H01L 25/16; H01L 27/12

(52) U.S. Cl. CPC H01L 33/507; H01L 25/167; H01L 27/1248; H01L 27/1259; H01L 33/502; H01L 2933/0041

(57) ABSTRACT

A display device includes a substrate including a display area and a first surface and a second surface opposite each other; and pixels in the display area and including an emission area and a non-emission area, respectively. Each of the pixels may include: a pixel circuit layer including one or more transistors on the first surface of the substrate in the non-emission area, and a first insulating layer, a second insulating layer, a third insulating layer and a fourth insulating layers that are sequentially stacked on the first surface of the substrate and respectively include an opening exposing the first surface of the substrate in the emission area; an optical layer on the pixel circuit layer; and a light emitting element layer on the optical layer. The optical layer may fill the opening of each of the first to fourth insulating layers in at least the emission area.

### CROSS-REFERENCE TO RELATED APPLICATION

This application claims priority to and the benefit of Korean Patent Application No. 10-2022-0143986 filed in the Korean Intellectual Property Office on Nov. 1, 2022, the entire content of which is incorporated by reference herein.

### BACKGROUND

### 1. Field

The present disclosure relates to a display device and a manufacturing method thereof.

### 2. Related Art

Recently, as interest in an information display is increasing, research and development for display devices are continuously conducted.

### SUMMARY

The present disclosure has been made in an effort to provide a display device and a manufacturing method thereof that may improve manufacturing efficiency.

One or more embodiments of the present disclosure provide a display device including: a substrate including a display area, the substrate having a first surface and a second surface opposite each other, and a plurality of pixels in the display area, the plurality of pixels including an emission area and a non-emission area. Each of the plurality of pixels may include: a pixel circuit layer including one or more transistors on the first surface of the substrate in the non-emission area, and a first insulating layer, a second insulating layer, a third insulating layer, and a fourth insulating layer that are sequentially stacked on the first surface of the substrate and respectively include an opening exposing the first surface of the substrate in the emission area; an optical layer on the pixel circuit layer; and a light emitting element layer on the optical layer and including a light emitting element that is electrically connected to at least one or more transistors to emit light. The optical layer may fill the opening of each of the first to fourth insulating layers in at least the emission area.

Each of the plurality of pixels may further include a second overcoat layer on the light emitting element layer. The second overcoat layer may include a material configured to block and absorb external light.

The first insulating layer may include a first opening exposing the first surface of the substrate in the emission area. The second insulating layer may include a second opening corresponding to the first opening in the emission area. The third insulating layer may include a third opening exposing the first surface of the substrate in the emission area. The fourth insulating layer may include a fourth opening corresponding to the third opening in the emission area.

The optical layer may include a color conversion layer in the emission area to correspond to the light emitting element and including color conversion particles; a color filter layer between the color conversion layer and the first surface of the substrate in at least the emission area, and configured to selectively transmit light emitted from the color conversion layer to the second surface of the substrate; and a first overcoat layer between the color filter layer and the light emitting element layer. The first overcoat layer may be on the optical layer covering the optical layer, the first overcoat layer may include an organic insulating layer having a flat surface.

The color filter layer may include a first color filter directly on the first surface of the substrate exposed by the first to fourth openings in at least the emission area and on the fourth insulating layer in at least the non-emission area; a second color filter on the first color filter in at least the non-emission area; and a third color filter on the second color filter in at least the non-emission area.

The color conversion layer may be on the first color filter in at least the emission area, and may be surrounded by the first to third color filters sequentially stacked in the non-emission area.

The first color filter may include a blue color filter, the second color filter may include a red color filter, and the third color filter may include a green color filter.

The light emitting element layer may include a first alignment electrode and a second alignment electrode on the first overcoat layer and spaced from each other; a fifth insulating layer on the first and second aligned electrodes; a bank in the non-emission area and including an opening portion corresponding to the emission area; the light emitting element in at least the emission area and located on the fifth insulating layer between the first alignment electrode and the second alignment electrode; a sixth insulating layer on the light emitting element and exposing a first end portion and a second end portion of the light emitting element; and a first electrode and a second electrode in at least the emission area, spaced from each other on the sixth insulating layer, and electrically connected to the light emitting element.

The first and second alignment electrodes may include a transparent conductive material, and the first and second electrodes may include an opaque conductive material.

The pixel circuit layer may further include a lower metal pattern between the first insulating layer and the first surface of the substrate in at least the non-emission area; a first power line configured to receive a voltage of a first driving power source; and a second power line configured to receive a voltage of a second driving power source different from the first driving power source. The lower metal pattern may be electrically connected to the at or more transistors.

The lower metal pattern may be a light blocking member blocking external light that is incident from the second surface of the substrate to the one or more transistors.

In at least the non-emission area, the first alignment electrode may be electrically connected to the first electrode through a first contact hole penetrating the fifth insulating layer. In at least the non-emission area, the second alignment electrode may be electrically connected to the second electrode through a second contact hole penetrating the fifth insulating layer. In at least the non-emission area, the second alignment electrode may be electrically connected to the second power line through a via hole penetrating the first overcoat layer, the color filter layer, and the fourth insulating layer.

The pixel circuit layer may further include a first light blocking pattern between the first surface of the substrate and the lower metal pattern in at least the non-emission area.

The plurality of pixels may be located on the first surface of the substrate, and may include a first pixel including a first emission area, a second pixel including a second emission area, and a third pixel including a third emission area. Each of the first to third pixels may include the pixel circuit layer, the optical layer, and the light emitting element layer.

The optical layer of the first pixel may include a first color conversion layer in the first emission area and including first color conversion particles; and a second color filter between the first color conversion layer and the first surface of the substrate in the first emission area. The optical layer of the second pixel may include a second color conversion layer in the second emission area and including second color conversion particles; and a third color filter between the second color conversion layer and the first surface of the substrate in the second emission area. The optical layer of the third pixel may include a light scattering layer in the third emission area and including light scattering particles; and a first color filter in the third emission area and located between the light scattering layer and the first surface of the substrate. The first color filter may be a blue color filter, the second color filter may be a red color filter, and the third color filter may be a green color filter.

Each of the first color conversion layer, the second color conversion layer, and the light scattering layer may be each surrounded by the first to third color filters sequentially stacked in the non-emission area.

The optical layer of the first pixel may include a first color conversion layer in the first emission area and including first color conversion particles; and a second light blocking pattern in a corresponding non-emission area adjacent to the first emission area and surrounding at least a portion of the first color conversion layer. The optical layer of the second pixel may include a second color conversion layer in the second emission area and including second color conversion particles; and the second light blocking pattern in a corresponding non-emission area adjacent to the second emission area and surrounding at least a portion of the second color conversion layer. The optical layer of the third pixel may include a light scattering layer in the third emission area and including light scattering particles; and the second light blocking pattern in a corresponding non-emission area adjacent to the third emission area and surrounding at least a portion of the light scattering layer.

The first color conversion layer may be on the first surface of the substrate in at least the first emission area. The second color conversion layer may be on the first surface of the substrate in at least the second emission area. The light scattering layer may be on the first surface of the substrate in at least the third emission area.

One or more embodiments of the present disclosure provide a display device including: a substrate including a display area and a non-display area, and a first surface and a second surface opposite each other; and a first pixel including a first emission area, a second pixel including a second emission area, and a third pixel including a third emission area, the first to third pixels being located on the first surface of the substrate. Each of the first to third pixels may include one or more transistors on the first surface of the substrate to correspond to a non-emission area between adjacent emission areas from among the first to third emission areas; a first insulating layer, a second insulating layer, a third insulating layer, and a fourth insulating layer, each of the first to fourth insulating layers including an opening exposing the first surface of the substrate in each of the first to third emission areas; a light blocking pattern on the third and fourth insulating layers in the non-emission area; a first overcoat layer on the first surface of the substrate in each of the first to third emission areas and on the light blocking pattern in at least the non-emission area; a light emitting element layer on the first overcoat layer and including a light emitting element electrically connected to the one or more transistors; and a second overcoat layer on the light emitting element layer. The light emitting element of the first pixel may be configured to emit red light, the light emitting element of the second pixel may be configured to emit green light, and the light emitting element of the third pixel may be configured to emit blue light.

One or more embodiments of the present disclosure provide a manufacturing method of a display device, including: preparing a substrate including a display area, and a first surface and a second surface opposite each other; and forming a plurality of pixels, each of the plurality of pixels including an emission area and a non-emission area on the first surface of the substrate. The forming of the plurality of pixels may include: forming a pixel circuit layer including one or more transistors on the first surface of the substrate corresponding to the non-emission area, and forming a first insulating layer, a second insulating layer, a third insulating layer, and a fourth insulating layer that are sequentially stacked on the first surface of the substrate and respectively include an opening exposing the first surface of the substrate in the emission area; forming an optical layer on the pixel circuit layer; and forming a light emitting element layer including a light emitting element emitting light on the optical layer.

The optical layer may fill the opening of each of the first to fourth insulating layers in at least the emission area.

According to one or more embodiments, a pixel circuit layer including transistors and insulating layers is formed on a substrate, a portion of each of the insulating layers is removed to form an opening exposing a first surface of the substrate, and an optical layer (for example, a color filter layer and/or a color conversion layer) is disposed in the opening to continuously form the pixel circuit layer and the optical layer, thereby reducing the number of masks. Accordingly, a display device with improved manufacturing efficiency may be provided.

According to one or more embodiments, a slimmer display device may be provided by using the pixel circuit layer and the optical layer as a planarization layer and forming a light emitting element layer thereon.

According to one or more embodiments, a manufacturing method of the display device described above may be provided.

Effects, aspects, and features of one or more embodiments of the present disclosure are not limited by what is illustrated in the above, and more various effects, aspects, and features are included in the present specification.

### BRIEF DESCRIPTION OF THE DRAWINGS

FIG. 1 illustrates a schematic perspective view of a light emitting element according to one or more embodiments.

FIG. 2 illustrates a schematic cross-sectional view of the light emitting element of FIG. 1.

FIG. 3 illustrates a schematic top plan view of a display device according to one or more embodiments.

FIG. 4 illustrates a schematic cross-sectional view of a display panel of FIG. 3.

FIG. 5 illustrates a schematic circuit diagram of an electrical connection relationship of constituent elements included in each of pixels illustrated in FIG. 3.

FIG. 6 illustrates a schematic top plan view of a light emitting element layer of a pixel according to one or more embodiments.

FIG. 7 to FIG. 9 illustrate schematic cross-sectional views taken along the line II-II′ of FIG. 6.

FIG. 10 illustrates a schematic cross-sectional view taken along the line III-III′ of FIG. 6.

FIG. 11 illustrates a schematic cross-sectional view taken along the line IV-IV′ of FIG. 6.

FIG. 12 to FIG. 24 illustrate schematic cross-sectional views taken along the line II-II′ of FIG. 6 for explaining a manufacturing method of a display device according to one or more embodiments.

FIG. 25 illustrates a pixel according to one or more embodiments, and illustrates a cross-sectional view taken along the line II-II′ of FIG. 6.

FIG. 26 to FIG. 29 illustrate schematic cross-sectional views taken along the line I-I′ of FIG. 3.

### DETAILED DESCRIPTION

Because the present disclosure may be variously modified and have various forms, embodiments will be illustrated and described in detail in the following. This, however, by no means restricts the present disclosure to the specific embodiments, and it is to be understood as embracing all included in the spirit and scope of the present disclosure changes, equivalents, and substitutes.

Like reference numerals are used for like constituent elements in describing each drawing. In the accompanying drawings, the dimensions of the structure are exaggerated and shown for clarity of the present disclosure. Terms such as first, second, and the like will be used only to describe various constituent elements, and are not to be interpreted as limiting these constituent elements. The terms are only used to differentiate one constituent element from other constituent elements. For example, a first constituent element could be termed a second constituent element, and similarly, a second constituent element could be termed as a first constituent element, without departing from the scope of the present disclosure.

In the present application, it should be understood that the term “include”, “comprise”, “have”, or “configure” indicates that a feature, a number, a step, an operation, a constituent element, a part, or a combination thereof described in the specification is present, but does not exclude a possibility of presence or addition of one or more other features, numbers, steps, operations, constituent elements, parts, or combinations, in advance. It will be understood that when an element such as a layer, film, region, area, or substrate is referred to as being “on” another element, it can be directly on the other element or intervening elements may also be present. In addition, in the present specification, when an element of a layer, film, region, area, plate, or the like is referred to as being formed “on” another element, the formed direction is not limited to an upper direction but includes a lateral or lower direction. In contrast, when an element of a layer, film, region, area, plate, or the like is referred to as being “below” another element, it may be directly below the other element, or intervening elements may be present.

It is to be understood that, in the present application, when it is described for one constituent element (for example, a first constituent element) to be (functionally or communicatively) “coupled or connected with/to” another constituent element (for example, a second constituent element), the one constituent element may be directly coupled or connected with/to the another constituent element, or may be coupled or connected with/to through the other constituent element (for example, a third constituent element). In contrast, it is to be understood that when it is described for one constituent element (for example, a first constituent element) to be “directly coupled or connected with/to” another constituent element (for example, a second constituent element), there is no other constituent element (for example, a third constituent element) between the one constituent element and the another constituent element.

Hereinafter, with reference to accompanying drawings, one or more embodiments of the present disclosure and others required for those skilled in the art to understand the contents of the present disclosure will be described in more detail. In the description below, singular forms are to include plural forms unless the context clearly indicates only the singular.

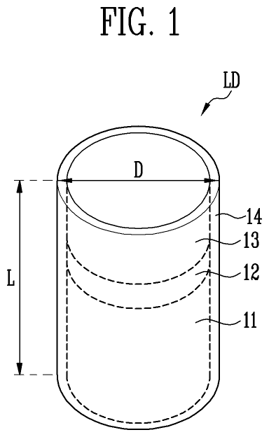

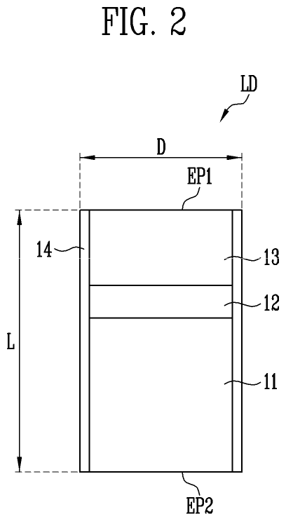

FIG. 1 illustrates a schematic perspective view of a light emitting element LD according to one or more embodiments, and FIG. 2 illustrates a schematic cross-sectional view of the light emitting element of FIG. 1.

Referring to FIG. 1 and FIG. 2, a light emitting element LD may include a first semiconductor layer 11, a second semiconductor layer 13, and an active layer 12 interposed between the first and second semiconductor layers 11 and 13. For example, the light emitting element LD may be implemented as a stacked light emitting body (or a stacked pattern) in which the first semiconductor layer 11, the active layer 12, and the second semiconductor layer 13 are sequentially stacked. A type and/or shape of the light emitting element LD are not limited to the embodiments shown in FIG. 1.

The light emitting element LD may be provided to have a shape extending in one direction. In case that an extending direction of the light emitting element LD is a length direction, the light emitting element LD may include a first end portion EP1 and a second end portion EP2 opposite each other along the length direction. One of the first semiconductor layer 11 and the second semiconductor layer 13 may be positioned on the first end portion EP1 of the light emitting element LD, and the other one of the first semiconductor layer 11 and the second semiconductor layer 13 may be positioned on the second end portion EP2 of the light emitting element LD. For example, the second semiconductor layer 13 may be positioned on the first end portion EP1 of the light emitting element LD, and the first semiconductor layer 11 may be positioned on the second end portion EP2 of the corresponding light emitting element LD.

The light emitting element LD may be provided in various shapes. For example, the light emitting element LD may have a rod-like shape, bar-like shape, or pillar shape that is long (or an aspect ratio larger than 1) in a length direction as shown in FIG. 1. As another example, the light emitting element LD may have a rod-like shape, bar-like shape, or pillar shape that is short (or an aspect ratio smaller than 1) in a length direction. As another example, the light emitting element LD may have a rod-like shape, bar-like shape, or pillar shape that has an aspect ratio of 1.

For example, the light emitting element LD may include a light emitting diode (LED) manufactured in an ultra-small size having a diameter D and/or a length L of nano scale (or nano meter) to micro scale (or micrometer).

In case that the light emitting element LD is long in a length direction (for example, an aspect ratio is larger than 1), the diameter D of the light emitting element LD may be about 0.5 μm to about 6 μm, and the length L thereof may be about 1 μm to about 10 μm. However, the diameter D and the length L of the light emitting element LD are not limited thereto, and the size of the light emitting element LD may be changed so that the light emitting element LD meets requirements (or design conditions) of a lighting device or a self-luminous display device to which the light emitting element LD is applied.

For example, the first semiconductor layer 11 may include at least one n-type semiconductor layer. For example, the first semiconductor layer 11 may include a semiconductor material of InAIGaN, GaN, AlGaN, InGaN, AlN, and/or InN, and/or may be a n-type semiconductor layer doped with a first conductive dopant (or n-type dopant) such as Si, Ge, Sn, or the like. However, the material included in the first semiconductor layer 11 is not limited thereto, and the first semiconductor layer 11 may be made of various materials.

The active layer 12 is disposed on the first semiconductor layer 11, and may be formed to have a single or multi-quantum well structure. For example, when the active layer 12 is formed of a multi-quantum well structure, the active layer 12 may have a structure in which a barrier layer, a strain reinforcing layer, and a well layer, which consist of one unit, are periodically and repeatedly stacked. Because the strain reinforcing layer has a smaller lattice constant than that of the barrier layer, it may further reinforce strain applied to the well layer, for example, compressive strain. However, the structure of the active layer 12 is not limited to the above-described embodiment.

The active layer 12 may emit light having a wavelength of 400 nm to 900 nm, and may have a double hetero-structure. In one or more embodiments, a clad layer doped with a conductive dopant may be formed above and/or below the active layer 12 along the length direction of the light emitting element LD. For example, the clad layer may be formed as an AlGaN layer or an InAIGaN layer. In one or more embodiments, a material such as AlGaN and InAIGaN may be used to form the active layer 12, and in addition, various materials may form the active layer 12. The active layer 12 may include the first surface contacting the first semiconductor layer 11 and the second surface contacting the second semiconductor layer 13.

In case that an electric field of a suitable voltage (e.g., a predetermined voltage) or more is applied to respective end portions of the light emitting element LD, the light emitting element LD emits light while electron-hole pairs are combined in the active layer 12. By controlling the light emission of the light emitting element LD by using this principle, the light emitting element LD may be used as a light source (or light emitting source) for various light emitting devices in addition to pixels of a display device.

The second semiconductor layer 13 is disposed on the second surface of the active layer 12, and may include a semiconductor layer of a type different from that of the first semiconductor layer 11. For example, the second semiconductor layer 13 may include at least one p-type semiconductor layer. For example, the second semiconductor layer 13 may include at least one semiconductor material of InAIGaN, GaN, AlGaN, InGaN, AlN, and/or InN, and may include a p-type semiconductor layer doped with a second conductive dopant (or p-type dopant) such as Mg, Zn, Ca, Sr, and/or Ba. However, the material included in the second semiconductor layer 13 is not limited thereto, and the second semiconductor layer 13 may be formed of various materials.

In one or more embodiments, the first semiconductor layer 11 and the second semiconductor layer 13 may have different thicknesses from each other in the length direction of the light emitting element LD. For example, the first semiconductor layer 11 may have a relatively thicker thickness than that of the second semiconductor layer 13 along the length direction of the light emitting element LD. Accordingly, the active layer 12 of the light emitting element LD may be disposed to be closer to the upper surface of the second semiconductor layer 13 than the lower surface of the first semiconductor layer 11.

In FIG. 1 and FIG. 2, it is illustrated that each of the first semiconductor layer 11 and the second semiconductor layer 13 is formed as one layer, but the present disclosure is not limited thereto. In one or more embodiments, each of the first semiconductor layer 11 and the second semiconductor layer 13 may further include at least one or more layers, for example, a cladding layer and/or a tensile strain barrier reducing (TSBR) layer according to the material of the active layer 12. The TSBR layer may be a strain reducing layer disposed between semiconductor layers having different lattice structures and serving as a buffer to reduce a difference in lattice constant, but is not limited thereto. The TSBR layer may be formed of a p-type semiconductor layer such as p-GalnP, p-AIInP, or p-AIGaInP, but is not limited thereto.

In one or more embodiments, the light emitting element LD may further include a contact electrode (hereinafter referred to as a “first contact electrode”) disposed on the second semiconductor layer 13 in addition to the first semiconductor layer 11, the active layer 12, and the second semiconductor layer 13 described above. In addition, in one or more embodiments, another contact electrode (hereinafter referred to as a “second contact electrode”) disposed on one end of the first semiconductor layer 11 may be further included.

Each of the first and second contact electrode electrodes may be an ohmic contact electrode, but is not limited thereto. In one or more embodiments, the first and second contact electrodes may be a Schottky contact electrode. The first and second contact electrodes may include a conductive material. For example, the first and second contact electrodes may include an opaque metal in which chromium (Cr), titanium (Ti), aluminum (Al), gold (Au), nickel (Ni), and/or an oxide or alloy thereof are used alone or in combination, but are not limited thereto. In one or more embodiments, the first and second contact electrodes may include a transparent conductive oxide such as an indium tin oxide (ITO), an indium zinc oxide (IZO), a zinc oxide (ZnOₓ), an indium gallium zinc oxide (IGZO), and/or an indium tin zinc oxide (ITZO). Here, the zinc oxide (ZnOₓ) may be a zinc oxide (ZnO) and/or a zinc peroxide (ZnO₂).

Materials included in the first and second contact electrodes may be the same or different from each other. The first and second contact electrodes may be substantially transparent or translucent. Accordingly, light generated by the light emitting element LD may transmit through each of the first and the second contact electrodes to be outputted to the outside of the light emitting element LD. In one or more embodiments, when the light generated by the light emitting element LD does not transmit through the first and second contact electrodes and is discharged to the outside through an area except for respective end portions of the light emitting element LD, the first and second contact electrodes may include an opaque metal.

In one or more embodiments, the light emitting element LD may further include an insulating property film 14 (hereinafter, referred to as an “insulating film”). However, in one or more embodiments, the insulating film 14 may be omitted, or it may be provided so as to cover only some of the first semiconductor layer 11, the active layer 12, and the second semiconductor layer 13.

The insulating film 14 may reduce or prevent an electrical short circuit that may occur when the active layer 12 contacts conductive materials other than the first and second semiconductor layers 11 and 13. In addition, the insulating film 14 may reduce or minimize surface defects of the light emitting element LD to improve lifespan and luminous efficiency of the light emitting element LD. In addition, in case that a plurality of light emitting elements LD are closely disposed, the insulating film 14 may prevent unwanted short circuits that may occur between the light emitting elements LD. As long as the active layer 12 may prevent a short circuit with an external conductive material from being caused, whether or not the insulating film 14 is provided is not limited.

The insulating film 14 may be provided in a form that entirely surrounds an outer surface (e.g., an outer peripheral or circumferential surface) of a light emitting stacked structure including the first semiconductor layer 11, the active layer 12, and the second semiconductor layer 13.

In the above-described embodiment, the structure in which the insulating film 14 entirely surrounds the outer surfaces (e.g., the outer peripheral or circumferential surfaces) of the first semiconductor layer 11, the active layer 12, and the second semiconductor layer 13 is described, but the present disclosure is not limited thereto. In one or more embodiments, in case that the light emitting element LD includes the first contact electrode, the insulating film 14 may entirely surround the outer surface (e.g., the outer peripheral or circumferential surface) of each of the first semiconductor layer 11, the active layer 12, the second semiconductor layer 13, and the first contact electrode. In addition, according to one or more embodiments, the insulating film 14 may not entirely surround the outer surface (e.g., the outer peripheral or circumferential surface) of the first contact electrode, or may only surround a portion of the outer surface (e.g., the outer peripheral or circumferential surface) of the first contact electrode and may not surround the remaining portion of the external surface (e.g., the external peripheral or circumferential surface) of the first contact electrode. In addition, in one or more embodiments, in case that the first contact electrode is disposed at the first end portion EP1 of the light emitting element LD and the second contact electrode is disposed at the second end portion EP2 of the light emitting element LD, the insulating film 14 may expose at least one area of each of the first and second contact electrodes.

The insulating film 14 may include a transparent insulating material. Various materials having insulating properties may be used as the material of the insulating film 14. The insulating film 14 may be provided in a form of a single layer or in a form of a multilayer including a double layer.

In one or more embodiments, the light emitting element LD may be implemented in a light emitting pattern having a core-shell structure.

The above-described light emitting element LD may be used as a light emitting source (or light source) for various display devices. The light emitting element LD may be manufactured through a surface treatment process. For example, when the plurality of light emitting elements LD are mixed with a fluid solution (or a solvent) and supplied to each pixel area (for example, an emission area of each pixel or an emission area of each sub pixel), each light emitting element LD may be surface-treated so that the light emitting elements LD may non-uniformly aggregated in the solution and may be uniformly sprayed.

An emission component (an emission device or emission unit) including the above-described light emitting element LD may be used in various types of electronic devices that require a display device and a light source. For example, in case that a plurality of light emitting elements LD are disposed in a pixel area of each pixel of a display panel, the light emitting elements LD may be used as a light source of each pixel. However, an application field of the light emitting element LD is not limited to the above-described example. For example, the light emitting element LD may be used in other types of electronic devices that require a light source, such as a lighting device.

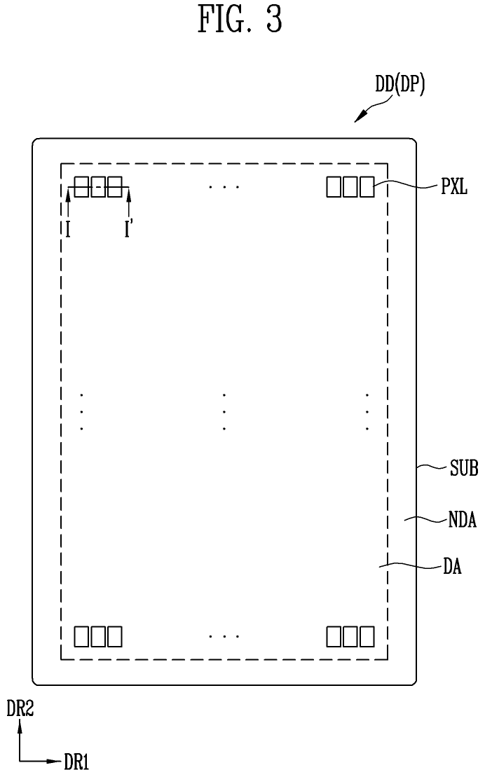

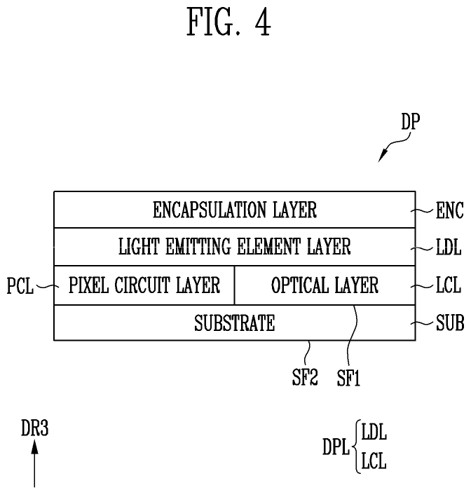

FIG. 3 illustrates a schematic top plan view of a display device DD according to one or more embodiments, and FIG. 4 illustrates a schematic cross-sectional view of a display panel DP of FIG. 3.

In FIG. 3 and FIG. 4, for better understanding and ease of description, a structure of the display device DD, particularly, of a display panel DP provided in the display device DD is briefly illustrated based on a display area DA in which an image is displayed.

Referring to FIG. 1 to FIG. 4, the display device DD may be classified into a passive matrix type of display device and an active matrix type of display device according to a method of driving the light emitting element LD. For example, when the display device DD is implemented as the active matrix type display device, each of the pixels PXL may include a driving transistor for controlling an amount of current supplied to the light emitting element LD, a switching transistor for transmitting a data signal to the driving transistor, and the like.

The display panel DP (or the display device DD) may include a substrate SUB, and pixels PXL disposed on the substrate SUB. Each of the pixels PXL may include at least one light emitting element LD.

The substrate SUB may include a transparent insulating material to transmit light. The substrate SUB may be a rigid substrate or a flexible substrate.

For example, the rigid substrate may be a glass substrate, a quartz substrate, a glass ceramic substrate, and/or a crystalline glass substrate.

The flexible substrate may be a film substrate and/or a plastic substrate, which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and/or cellulose acetate propionate.

One area on the substrate SUB is provided as the display area DA in which pixels PXL are disposed, and the remaining area on the substrate SUB may be provided as a non-display area NDA. For example, the substrate SUB may include the display area DA including pixel areas PXA in which respective pixels PXL are disposed, and the non-display area NDA disposed around the display area DA (or adjacent to the display area DA) along an edge or periphery of the display area DA.

The substrate SUB may include a first surface SF1 and a second surface SF2 opposite each other in a thickness direction of the substrate SUB, for example, a third direction DR3. The first surface SF1 (or an upper surface) may be one surface of the substrate SUB on which the pixel PXL is provided, and the second surface SF2 (or a lower surface) may be an image display surface on which an image is displayed.

Each of the pixels PXL may be provided in the display area DA on the substrate SUB. In one or more embodiments, the pixels PXL may be arranged in the display area DA in a stripe arrangement structure, but is not limited thereto.

Each pixel PXL may include a pixel circuit layer PCL, a display element layer DPL, and an encapsulation layer ENC positioned on the first surface SF1 of the substrate SUB.

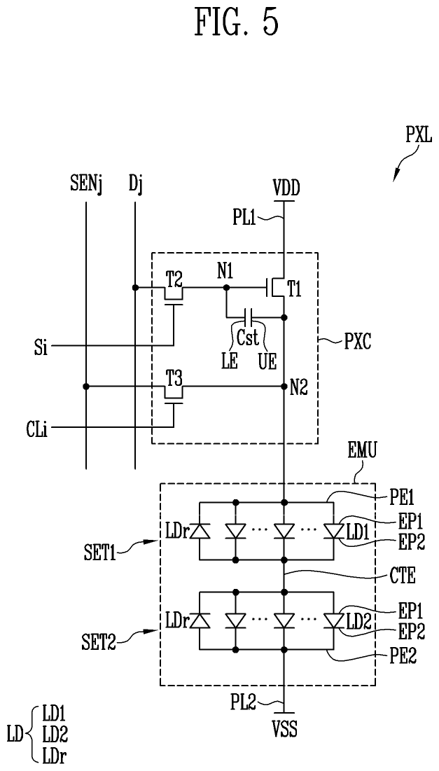

The pixel circuit layer PCL is disposed on the first surface SF1 of the substrate SUB, and a pixel circuit including a plurality of transistors (refer to “PXC” in FIG. 5), signal lines electrically connected to the transistors, and a plurality of insulating layers may be disposed on the pixel circuit layer PCL. Each transistor, for example, may have a structure in which a semiconductor pattern, a gate electrode, a first terminal, and a second terminal are sequentially stacked with an insulating layer interposed therebetween. The semiconductor pattern may include an amorphous silicon, a poly silicon, a low temperature poly silicon, an organic semiconductor, and/or an oxide semiconductor. The gate electrode, the first terminal (or a source electrode), and the second terminal (or a drain electrode) may include one of aluminum (Al), copper (Cu), titanium (Ti), and/or molybdenum (Mo), but the present disclosure is not limited thereto.

The display element layer DPL may include an optical layer LCL and a light emitting element layer LDL.

In one or more embodiments, the optical layer LCL may be inserted into an opening penetrating insulating layers included in the pixel circuit layer PCL in one area of the substrate SUB to be provided between the first surface SF1 of the substrate SUB and the light emitting element layer LDL. In this case, the pixel circuit layer PCL may not be disposed in one area of the substrate SUB. For better understanding and ease of description, the pixel circuit layer PCL and the optical layer LCL are illustrated on (or at) the same layer, but are not limited thereto. The optical layer LCL may be disposed on the pixel circuit layer PCL in another area of the substrate SUB.

The optical layer LCL may convert light emitted from the light emitting element layer LDL and proceeding to a direction of the second surface SF2 of the substrate SUB (or a direction of the pixel circuit layer PCL) into light having excellent color reproducibility to emit the converted light. The optical layer LCL may include a color filter layer and a color conversion layer. In one or more embodiments, the optical layer LCL may include only a color conversion layer.

The light emitting element layer LDL may be disposed on the optical layer LCL and/or the pixel circuit layer PCL. An emission component (refer to “EMU” in FIG. 5) including the light emitting element LD emitting light may be positioned on the light emitting element layer LDL. A first electrode and a second electrode electrically connected to the light emitting element LD may be disposed in the emission component EMU.

The encapsulation layer ENC may be disposed on the display element layer DPL (or the light emitting element layer LDL). The encapsulation layer ENC may alleviate a step caused by the components positioned thereunder, for example, the display element layer DPL, and may reduce or prevent external air and moisture from penetrating into the display element layer DPL. The encapsulation layer ENC may include a material that absorbs and/or blocks light in order to block external light from being introduced into the display element layer DPL. For example, the encapsulation layer ENC may include a black matrix, but is not limited thereto.

FIG. 5 illustrates a schematic circuit diagram of an electrical connection relationship of constituent elements included in each of the pixels PXL illustrated in FIG. 3.

For example, FIG. 5 illustrates an electrical connection relationship between constituent elements included in the pixel PXL applicable to an active matrix type of a display device according to one or more embodiments. However, the electrical connection relationship between the constituent elements of each pixel PXL is not limited thereto.

Referring to FIG. 1 to FIG. 5, the pixel PXL may include the emission component EMU that generates light with luminance corresponding to a data signal. In addition, the pixel PXL may selectively further include the pixel circuit PXC for driving the emission component EMU.

For example, the emission component EMU may include a first electrode PE1 (or a “first pixel electrode”) electrically connected to the first power source VDD through the pixel circuit PXC and the first power line PL1, a second electrode PE2 (or a “second pixel electrode”) electrically connected to the second power source VSS through the second power line PL2, and a plurality of light emitting elements LD electrically connected between the first and second electrodes PE1 and PE2. The first and second driving power sources VDD and VSS may have different potentials so that the light emitting elements LD may emit light. For example, the first driving power source VDD may be set as a high potential power source, and the second driving power source VSS may be set as a low potential power source.

In one or more embodiments, the emission component EMU may include at least one serial stage. Each serial stage may include a pair of electrodes (for example, two electrodes) and at least one light emitting element LD electrically connected in a forward direction between the pair of electrodes. Here, the number of serial stages forming the emission component EMU and the number of light emitting elements LD forming each serial stage are not particularly limited. For example, the number of the light emitting elements LD configuring respective serial stages may be the same or different from each other, but the number of the light emitting elements LD is not particularly limited.

The emission component EMU may include, for example, a first serial stage SET1 including at least one first light emitting element LD1 and a second serial stage SET2 including at least one second light emitting element LD2.

The first serial stage SET1 may include the first electrode PE1 and an intermediate electrode CTE (or a bridge electrode), and at least one first light emitting element LD1 electrically connected between the first electrode PE1 and the intermediate electrode CTE. Each first light emitting element LD1 may be connected in a forward direction between the first electrode PE1 and the intermediate electrode CTE. For example, the first end portion EP1 of the first light emitting element LD1 may be electrically connected to the first electrode PE1, and the second end portion EP2 of the first light emitting element LD1 may be electrically connected to the intermediate electrode CTE.

The second serial stage SET2 may include the intermediate electrode CTE and the second electrode PE2, and at least one second light emitting element LD2 electrically connected between the intermediate electrode CTE and the second electrode PE2. Each second light emitting element LD2 may be connected in a forward direction between the intermediate electrode CTE and the second electrode PE2. For example, the first end portion EP1 of the second light emitting element LD2 may be electrically connected to the intermediate electrode CTE, and the second end portion EP2 of the second light emitting element LD2 may be electrically connected to the second electrode PE2.

A first electrode of the emission component EMU, for example, the first electrode PE1 may be an anode electrode of the emission component EMU. A last electrode of the emission component EMU, for example, the second electrode PE2 may be a cathode electrode of the emission component EMU.

In case that the light emitting elements LD are connected in a serial/parallel structure, power efficiency may be improved compared with when the same number of light emitting elements LD are connected only in parallel. In addition, in the pixel PXL in which the light emitting elements LD are connected in a serial/parallel structure, because a suitable luminance (e.g., a predetermined luminance) may be displayed through some light emitting elements LD of the serial stage, the possibility of dark spot defects of the pixel PXL may be reduced. However, the present disclosure is not limited thereto, and the emission component EMU may be configured by connecting the light emitting elements LD only in series or only in parallel.

Each of the light emitting elements LD may include at least one electrode (for example, the first electrode PE1), the first end portion EP1 (for example, a p-type end portion) electrically connected to the first driving power source VDD via the pixel circuit PXC and/or the first power line PL1, and the second end portion EP2 (for example, an n-type end portion) electrically connected to the second driving power source VSS via at least one other electrode (for example, the second electrode PE2) and the second power line PL2. For example, the light emitting elements LD may be electrically connected in a forward direction between the first driving power source VDD and the second driving power source VSS. The light emitting elements LD electrically connected to the forward direction may configure the effective light sources of the emission component EMU.

In one or more embodiments, the emission component EMU may further include at least one reverse light emitting element LDr, in addition to the light emitting elements LD forming respective effective light sources.

The light emitting elements LD of the emission component EMU may emit light with luminance corresponding to a driving current supplied through the corresponding pixel circuit PXC. For example, during each frame period, the pixel circuit PXC may supply a driving current corresponding to a gray value of the corresponding frame to the emission component EMU. The driving current supplied to the emission component EMU may be divided to flow in each of the light emitting elements LD. Therefore, while each light emitting element LD emits light with a luminance corresponding to the current flowing therein, the emission component EMU may emit light having a luminance corresponding to the driving current.

The pixel circuit PXC may be electrically connected to a scan line Si and a data line Dj of the pixel PXL. For example, in case that the pixel PXL is disposed in an i-th row and a j-th column of the display area DA, the pixel circuit PXC of the pixel PXL may be electrically connected to an i-th scan line Si and a j-th data line Dj of the display area DA. In addition, the pixel circuit PXC may be electrically connected to an i-th control line CLi and a j-th sensing line SENj of the display area DA.

The pixel circuit PXC described above may include first to third transistors T1, T2, and T3 and a storage capacitor Cst.

The first transistor T1 is a driving transistor for controlling a driving current applied to the emission component EMU, and may be electrically connected between the first driving power source VDD and the emission component EMU. For example, a first terminal of the first transistor T1 may be electrically connected to the first driving power source VDD through the first power line PL1, a second terminal of the first transistor T1 may be electrically connected to a second node N2, and a gate electrode of the first transistor T1 may be electrically connected to a first node N1. The first transistor T1 may control an amount of the driving current applied to the emission component EMU from the first driving power source VDD through the second node N2 according to a voltage applied to the first node N1. In one or more embodiments, the first terminal of the first transistor T1 may be a drain electrode, and the second terminal of the first transistor T1 may be a source electrode, but the present disclosure is not limited thereto. In one or more embodiments, the first terminal thereof may be a source electrode, and the second terminal thereof may be a drain electrode.

The second transistor T2 is a switching transistor that selects the pixel PXL in response to a scan signal and activates the pixel PXL, and may be electrically connected between the data line Dj (for example, the j-th data line) and the first node N1. A first terminal of the second transistor T2 may be electrically connected to the data line Dj, a second terminal of the second transistor T2 may be electrically connected to the first node N1 (or the gate electrode of the first transistor T1), and a gate electrode of the second transistor T2 may be electrically connected to the scan line Si (for example, the i-th scan line). The first terminal and the second terminal of the second transistor T2 are different terminals, and for example, when the first terminal is a drain electrode, the second terminal may be a source electrode.

In case that a scan signal of a gate-on voltage (for example, a high level voltage) is supplied from the scan line Si, the second transistor T2 may be turned on to electrically connect the data line Dj and the first node N1. The first node N1 is a point at which the second terminal of the second transistor T2 is connected to the gate electrode of the first transistor T1, and the second transistor T2 may transmit a data signal to the gate electrode of the first transistor T1.

The third transistor T3 connects the first transistor T1 to the sensing line SENj (for example, the j-th sensing line), so that it may obtain a sensing signal through the sensing line SENj, and may detect a characteristic of the pixel PXL in addition to a threshold voltage of the first transistor T1 by using the sensing signal. Information on the characteristics of the pixel PXL may be used to convert image data so that a characteristic difference between the pixels PXL may be compensated. A second terminal of the third transistor T3 may be electrically connected to the second terminal of the first transistor T1 and the second node N2, a first terminal of the third transistor T3 may be electrically connected to the sensing line SENj, and a gate electrode of the third transistor T3 may be electrically connected to the control line CLi (for example, the i-th control line). In addition, in one or more embodiments, the first terminal of the third transistor T3 may be electrically connected to an initialization power source. The third transistor T3 is an initialization transistor capable of initializing the second node N2, and in case that a sensing control signal is supplied from the control line CLi, the third transistor T3 may be turned on to transmit a voltage of the initialization power source to the second node N2. Accordingly, an upper electrode UE (or a second storage electrode) of the storage capacitor Cst electrically connected to the second node N2 may be initialized.

The storage capacitor Cst may include a lower electrode LE (or a first storage electrode) and the upper electrode UE (or the second storage electrode). The lower electrode LE may be electrically connected to the first node N1, and the upper electrode UE may be electrically connected to the second node N2. The storage capacitor Cst is charged with a data voltage corresponding to the data signal supplied to the first node N1 during one frame period. Accordingly, the storage capacitor Cst may store a voltage corresponding to a difference between a voltage of the gate electrode of the first transistor T1 and a voltage of the second node N2.

FIG. 5 illustrates one or more embodiments in which the first to third transistors T1, T2, and T3 are all N-type transistors, but the present disclosure is not limited thereto. For example, at least one of the first to third transistors T1, T2, and T3 may be changed to a P-type transistor. In one or more embodiments, the emission component EMU may be electrically connected between the first driving power source VDD and the pixel circuit PXC.

The structure of the pixel circuit PXC may be variously changed. For example, the pixel circuit PXC may additionally include other circuit elements such as at least one transistor element such as a transistor element for initializing the first node N1 and/or a transistor element for controlling a light emission time of the light emitting elements LD, or a boosting capacitor for boosting the voltage of the first node N1.

In the following embodiment, for better understanding and ease of description, a horizontal direction (or an X-axis direction) in a plan view is indicated as the first direction DR1, a vertical direction (or a Y-axis direction) in a plan view is indicated as the second direction DR2, and a vertical direction in a cross-sectional view is indicated as the third direction DR3.

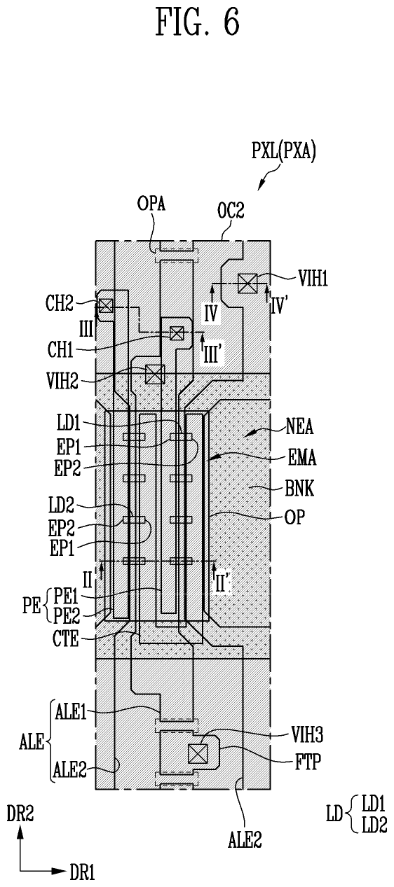

FIG. 6 illustrates a schematic top plan view of a of light emitting element layer of the pixel PXL according to one or more embodiments.

In FIG. 6, for convenience of description, the transistors electrically connected to the light emitting elements LD and the signal lines electrically connected to the transistors are omitted.

In the following embodiment, not only the constituent elements included in the pixel PXL illustrated in FIG. 6 but also the area in which the constituent elements are provided (or positioned) are comprehensively referred to as the pixel PXL.

Referring to FIG. 1 to FIG. 6, the pixel PXL may be positioned in the pixel area PXA provided on the substrate SUB. The pixel area PXA may include an emission area EMA emitting light and a non-emission area NEA not emitting light.

The pixel PXL may include a bank BNK positioned in the non-emission area NEA and light emitting elements LD positioned in the emission area EMA.

The bank BNK may define an area in which the light emitting elements LD are to be supplied in a process of supplying (or injecting) the light emitting elements LD to the pixel PXL. For example, supply positions of the light emitting elements LD is partitioned by the bank BNK, so that a mixed solution (for example, ink) including a target amount and/or type of light emitting element LD may be supplied to (or injected into) the emission area EMA.

The bank BNK may be configured to include at least one light blocking material and/or at least one reflective material (or scattering material) to prevent light leakage from occurring between the pixel PXL and pixels PXL adjacent thereto. In one or more embodiments, the bank BNK may include a transparent material (or substance). The transparent material may include, for example, a polyamides resin, a polyimide resin, and the like, but is not limited thereto. According to one or more embodiments, a reflective material layer may be separately provided and/or formed on the bank BNK to further improve an efficiency of light emitted from the pixel PXL.

The bank BNK may include at least one opening portion OP exposing components positioned thereunder in the pixel area PXA. The opening portion OP of the bank BNK may be the supply position of light emitting elements LD or the emission area EMA of the pixel PXL.

An electrode separating area OPA may be positioned in the non-emission area NEA of each pixel PXL. The electrode separating area OPA may be an area in which a first alignment electrode ALE1 in each pixel PXL is separated from a first alignment electrode ALE1 provided in the pixel PXL adjacent in the second direction DR2.

The light emitting element layer LDL (or the emission component EMU) includes an electrode PE (or a pixel electrode) provided in the emission area EMA, light emitting elements LD electrically connected to the electrode PE, and alignment electrodes ALE provided at positions corresponding to the electrode PE. For example, in the emission area EMA, a first electrode PE1 (or a first pixel electrode), a second electrode PE2 (or a second pixel electrode), light emitting elements LD, first and second alignment electrodes ALE1 and ALE2 are disposed. The number, shape, size, and arrangement of the electrodes PE and/or the alignment electrodes ALE may be variously changed according to the structure of the pixel PXL (particularly, the emission component EMU).

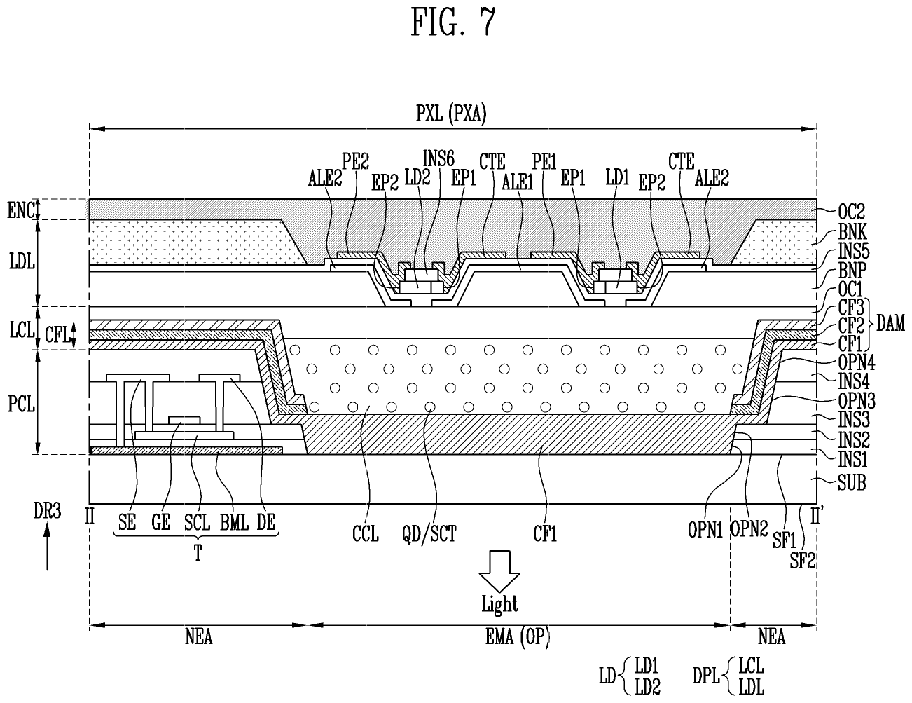

In one or more embodiments, the alignment electrodes ALE, the light emitting elements LD, and the electrodes PE may be sequentially provided based on one surface of the substrate SUB on which the pixel PXL is provided, but the present disclosure is not limited thereto. In one or more embodiments, the position and the shape order of the electrode patterns configuring the emission component EMU may be variously changed. The stacked structure (or cross-sectional structure) of the pixel PXL will be described later with reference to FIG. 7 to FIG. 11.

The alignment electrodes ALE may be positioned in at least emission area EMA, may be spaced from each other along the first direction DR1 in the emission area EMA, and may respectively extend in the second direction DR2. The alignment electrodes ALE may include the second alignment electrode ALE2, the first alignment electrode ALE1, and another second alignment electrode ALE2 arranged to be spaced from each other along the first direction DR1.

At least one of the second alignment electrode ALE2, the first alignment electrode ALE1, and another second alignment electrode ALE2 may be separated from another electrode (for example, the alignment electrode ALE provided in the adjacent pixel PXL adjacent to each pixel PXL in the second direction DR2), after the light emitting elements LD are supplied and aligned in the emission area EMA during the manufacturing process of the display device DD. As an example, the first alignment electrode ALE1 may be separated from the first alignment electrode ALE1 provided in the adjacent pixels PXL adjacent to the corresponding pixel PXL, after the light emitting elements LD are supplied and aligned in the emission area EMA during the manufacturing process of the display device DD.

For example, in one or more embodiments, the first alignment electrodes ALE1 provided in the display area DA may be formed to be connected to each other in a manufacturing process of the display device DD (or the pixel PXL). For example, the first alignment electrodes ALE1 may be formed to be integrally connected with a floating pattern FTP to configure a first alignment line. The floating pattern FTP may be electrically connected to some components of the pixel circuit layer PCL, for example, the first power line (refer to “PL1” in FIG. 5) through a third via hole VIH3. In the alignment process of the light emitting elements LD, the first alignment signal may be supplied to the first alignment line through the first power line PL1. After the alignment process of the light emitting elements LD is completed, a portion of the first alignment line is removed (or the first alignment line is cut) from the periphery of the third via hole VIH3 positioned in the non-emission area NEA, so that an electrical connection between the first alignment electrodes ALE1 and the first power line PL1 may be disconnected. For example, by cutting the first alignment line in the electrode separating area OPA positioned around the floating pattern FTP, the first alignment line may be separated into the first alignment electrodes ALE1 and the floating patterns FTP. In addition, the first alignment electrodes ALE1 of the adjacent pixels PXL may be separated by cutting the first alignment line in the electrode separating area OPA between the adjacent pixel columns. Accordingly, the first alignment electrodes ALE1 of the pixels PXL positioned in the same pixel column are electrically separated from each other, so that the pixels PXL may be individually driven.

In a plan view, the second alignment electrode ALE2, the first alignment electrode ALE1, and another second alignment electrode ALE2 may be sequentially arranged along the first direction DR1 in the emission area EMA. The second alignment electrode ALE2 may be positioned adjacent to one side (for example, the left side) of the first alignment electrode ALE1, and the another second alignment electrode ALE2 may be positioned adjacent to the other side (for example, the right side) of the first alignment electrode ALE1.

The first alignment electrode ALE1 may be electrically connected to some components of the pixel circuit PXC, for example, the upper electrode (refer to “UE” in FIG. 5) of the storage capacitor (refer to “Cst” in FIG. 5), through a second via hole VIH2. The second via hole VIH2 may be formed by opening a partial area of an insulating layer positioned between the first alignment electrode ALE1 and the upper electrode UE of the storage capacitor Cst.

Another second alignment electrode ALE2 may be electrically connected to some components electrically connected to the pixel circuit PXC, for example, the second power line (refer to “PL2” in FIG. 5), through a first via hole VIHI1. The first via hole VIH1 may be formed by opening a partial area of an insulating layer positioned between the another second alignment electrode ALE2 and the second power line PL2.

Each of the second alignment electrode ALE2, the first alignment electrode ALE1, and the another second alignment electrode ALE2 in the emission area EMA may be disposed to be spaced from the adjacent alignment electrode ALE in the first direction DR1. The second alignment electrodes ALE2 may be non-integrally or integrally formed with the second alignment electrodes ALE2 positioned in the adjacent pixel PXL (e.g., in the first direction DR1) to be electrically connected thereto. For example, the second alignment electrode ALE2 may be electrically connected to another second alignment electrode ALE2 of the adjacent pixel PXL, and the another second alignment electrode ALE2 may be electrically connected to the second alignment electrode ALE2 of the adjacent pixel PXL (e.g., in the first direction DR1).

Each of the second alignment electrode ALE2, the first alignment electrode ALE1, and the another second alignment electrode ALE2 may receive an alignment signal before the light emitting elements LD are aligned in the emission area EMA of each pixel PXL, and may be used as an alignment line for aligning light emitting elements LD.

The first alignment electrode ALE1 may receive the first alignment signal in the alignment step of the light emitting elements LD, and the second alignment electrode ALE2 and the another second alignment electrode ALE2 may receive the second alignment signal in the alignment step of the light emitting elements LD. The above-described first and second alignment signals may be signals having a voltage difference and/or a phase difference sufficient to align the light emitting elements LD between the alignment electrodes ALE. At least one of the first and second alignment signals may be an AC signal, but is not limited thereto.

The second alignment electrode ALE2, the first alignment electrode ALE1, and the another second alignment electrode ALE2 may be provided in a bar shape having a constant width in the at least emission area EMA, but are not limited thereto. The second alignment electrode ALE2, the first alignment electrode ALE1, and the another second alignment electrode ALE2 may or may not have a curved portion in the non-emission area NEA, and a shape and/or size of an area other than the area that is in the emission area EMA is not particularly limited and may be variously changed.

At least two to several tens of light emitting elements LD may be aligned and/or provided in the emission area EMA (or the pixel area PXA), but the number of the light emitting elements LD is but is not limited thereto. In one or more embodiments, the number of light emitting elements LD aligned and/or provided in the emission area EMA (or the pixel area PXA) may be variously changed.

The light emitting elements LD may be respectively disposed between the second alignment electrode ALE2 and the first alignment electrode ALE1 and between the first alignment electrode ALE1 and another second alignment electrode ALE2. In a plan view, each of the light emitting elements LD may include a first end portion EP1 and a second end portion EP2 positioned at respective ends thereof (e.g., positioned opposite each other) in a length direction thereof, for example, the first direction DR1. In one or more embodiments, a second semiconductor layer (refer to “13” in FIG. 1) including a p-type semiconductor layer may be positioned at the first end portion EP1 (or the p-type end portion), and a first semiconductor layer (refer to “11” of FIG. 1) including an n-type semiconductor layer may be positioned at the second end portion EP2 (or the n-type end portion). The light emitting elements LD may be electrically connected in parallel to each other between the second alignment electrode ALE2 and the first alignment electrode ALE1 and between the first alignment electrode ALE1 and another second alignment electrode ALE2, respectively.

The light emitting elements LD may be disposed to be spaced from each other, and may be aligned substantially parallel to each other. A distance at which the light emitting elements LD are spaced from each other is not particularly limited. In one or more embodiments, a plurality of light emitting elements LD are disposed adjacent to each other to form a group, and a plurality of other light emitting elements LD may be grouped in a state of being spaced from each other by a suitable distance (e.g., a predetermined distance), and may have non-uniform density and may also be aligned in one direction.

The light emitting elements LD may be injected (or supplied) into the pixel area PXA (the “emission area EMA” or the “opening portion OP of the bank BNK”) through various methods including an inkjet printing method and a slit coating method. For example, the light emitting elements LD may be mixed with a volatile solvent and then injected (or supplied) into the pixel area PXA through an inkjet printing method or a slit coating method.

The light emitting elements LD may include the first light emitting element LD1 and the second light emitting element LD2.

The first light emitting element LD1 may be aligned between the right side of the first alignment electrode ALE1 and the another second alignment electrode ALE2 to be electrically connected to the first electrode PE1 and the intermediate electrode CTE. The second light emitting element LD2 may be aligned between the left side of the first alignment electrode ALE1 and the second alignment electrode ALE2 to be electrically connected to the intermediate electrode CTE and the second electrode PE2.

A plurality of first light emitting elements LD1 and second light emitting elements LD2 may be provided. The first end portion EP1 of each of the first light emitting elements LD1 may be electrically connected to the first electrode PE1, and the second end portion EP2 of each of the first light emitting elements LD1 may be electrically connected to the intermediate electrode CTE. The first end portion EP1 of each of the second light emitting elements LD2 may be electrically connected to the intermediate electrode CTE, and the second end portion EP2 of each of the second light emitting elements LD2 may be electrically connected to the second electrode PE2.

The first light emitting elements LD1 may be mutually connected in parallel between the first electrode PE1 and the intermediate electrode CTE, and the second light emitting elements LD2 may be mutually connected in parallel between the intermediate electrode CTE and the second electrode PE2.

The electrodes PE and the intermediate electrode CTE may be provided in the at least emission area EMA of the pixel PXL, and may be provided at positions corresponding to at least one alignment electrode ALE and the light emitting elements LD, respectively. For example, each electrode PE and each intermediate electrode CTE may be formed on each alignment electrode ALE and a corresponding light emitting elements LD so as to overlap the each alignment electrode ALE and the corresponding light emitting elements LD to be electrically connected to at least light emitting elements LD.

The electrodes PE may include a first electrode PE1 and a second electrode PE2 disposed to be spaced from each other.

The first electrode PE1 (“first pixel electrode” or “anode”) may be formed on the right side of the first alignment electrode ALE1 and on the first end portion EP1 of each of the first light emitting elements LD1 to be electrically connected to the first end portion EP1 of each of the first light emitting elements LD1. The first electrode PE1 may have a bar shape having a constant width along an extension direction thereof, for example, the second direction DR2.

The second electrode PE2 (“second pixel electrode” or “cathode”) may be formed on the second alignment electrodes ALE2 and on the second end portion EP2 of each of the second light emitting elements LD2 to be electrically connected to the second end portion EP2 of each of the second light emitting elements LD2. The second electrode PE2 may have a bar shape having a constant width along an extension direction thereof, for example, the second direction DR2.

The intermediate electrode CTE may be formed on the another second alignment electrodes ALE2 and on the second end portion EP2 of each of the first light emitting elements LD1 to be electrically connected to the second end portion EP2 of each of the first light emitting elements LD1. In addition, the intermediate electrode CTE may be formed on the left side of the first alignment electrode ALE1 and on the first end portion EP1 of each of the second light emitting elements LD2 to be electrically connected to the first end portion EP1 of each of the second light emitting elements LD2. The intermediate electrode CTE may have a curved shape. For example, the intermediate electrode CTE may have a curved or bent structure at a boundary between an area in which at least one first light emitting element LD1 is arranged and an area in which at least one second light emitting element LD2 is arranged.

The first electrode PE1, the intermediate electrode CTE, and the second electrode PE2 may be disposed to be spaced from each other in the emission area EMA.

In the above-described manner, the light emitting elements LD aligned between the alignment electrodes ALE may be connected in a desired form by using the first electrode PE1, the intermediate electrode CTE, and the second electrode PE2. For example, the first light emitting elements LD1 and the second light emitting elements LD2 may be sequentially electrically connected in series by using the first electrode PE1, the intermediate electrode CTE, and the second electrode PE2.

In one or more embodiments, the first electrode PE1 may be an anode of the emission component EMU, and the second electrode PE2 may be a cathode of the emission component EMU.

The first electrode PE1 may contact the first alignment electrode ALE1 through a first contact hole CH1 in the at least non-emission area NEA to be electrically connected to the first alignment electrode ALE1. The first contact hole CH1 may be formed by opening a portion of at least one insulating layer positioned between the first electrode PE1 and the first alignment electrode ALE1, and a portion of the first alignment electrode ALE1 may be exposed by the first contact hole CH1. The first contact hole CH1 has been described as being positioned in the non-emission area NEA, but is not limited thereto. In one or more embodiments, the first contact hole CH1 may be positioned in the emission area EMA of the pixel PXL.

The pixel circuit PXC (or the upper electrode UE), the first alignment electrode ALE1, and the first electrode PE1 may be electrically connected through the second via hole VIH2 and the first contact hole CH1. In the described embodiment, it has been described that the first alignment electrode ALE1 and the first electrode PE1 are directly contacted and connected through the first contact hole CH1, but the present disclosure is not limited thereto. In one or more embodiments, in order to prevent a defect due to material characteristics of the first alignment electrode ALE1, the first electrode PE1 may be in direct contact with the pixel circuit PXC, without directly contacting the first alignment electrode ALE1, to be electrically connected to the pixel circuit PXC.

The second electrode PE2 may be directly contacted to the second alignment electrode ALE2 through a second contact hole CH2 to be electrically and/or physically connected to the second alignment electrode ALE2. The second contact hole CH2 may be formed by opening a portion of at least one insulating layer positioned between the second electrode PE2 and the second alignment electrode ALE2, and a portion of the second alignment electrode ALE2 may be exposed by the second contact hole CH2. In one or more embodiments, the second contact hole CH2 may be positioned in the emission area EMA of the pixel PXL.

The second power line PL2, the second alignment electrode ALE2, and the second electrode PE2 may be electrically connected to each other through the first via hole VIH1 and the second contact hole CH2.

In the described embodiment, it has been described that the second alignment electrode ALE2 and the second electrode PE2 are directly contacted and connected through the second contact hole CH2, but the present disclosure is not limited thereto. In one or more embodiments, in order to prevent a defect due to material characteristics of the second alignment electrode ALE2, the second electrode PE2 may directly contact the second power line PL2, without directly contacting the second alignment electrode ALE2, to be electrically connected to the second power line PL2.

In one or more embodiments, the pixel PXL may further include a second overcoat layer OC2 entirely positioned on the light emitting element layer LDL.

The second overcoat layer OC2 may include a light blocking material that blocks light incident to the light emitting element layer LCL from the outside. For example, the second overcoat layer OC2 may include a black matrix.

Hereinafter, a stacked structure (or a cross-sectional structure) of the pixel PXL according to the above-described embodiment will be mainly described with reference to FIG. 7 to FIG. 11.

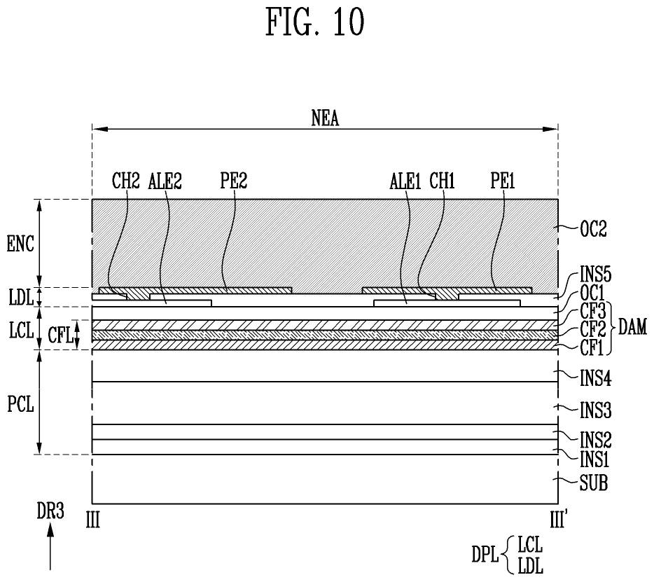

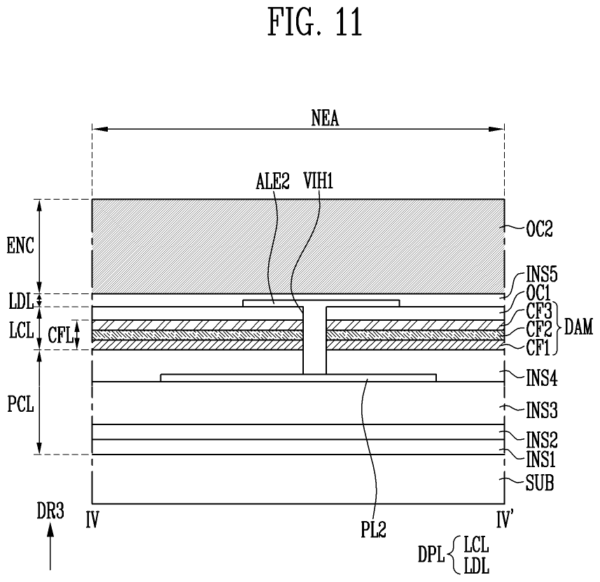

FIG. 7 to FIG. 9 illustrate schematic cross-sectional views taken along the line II-II′ of FIG. 6, FIG. 10 illustrates a schematic cross-sectional view taken along the line III-III′ of FIG. 6, and FIG. 11 illustrates a schematic cross-sectional view taken along the line IV-IV′ of FIG. 6.

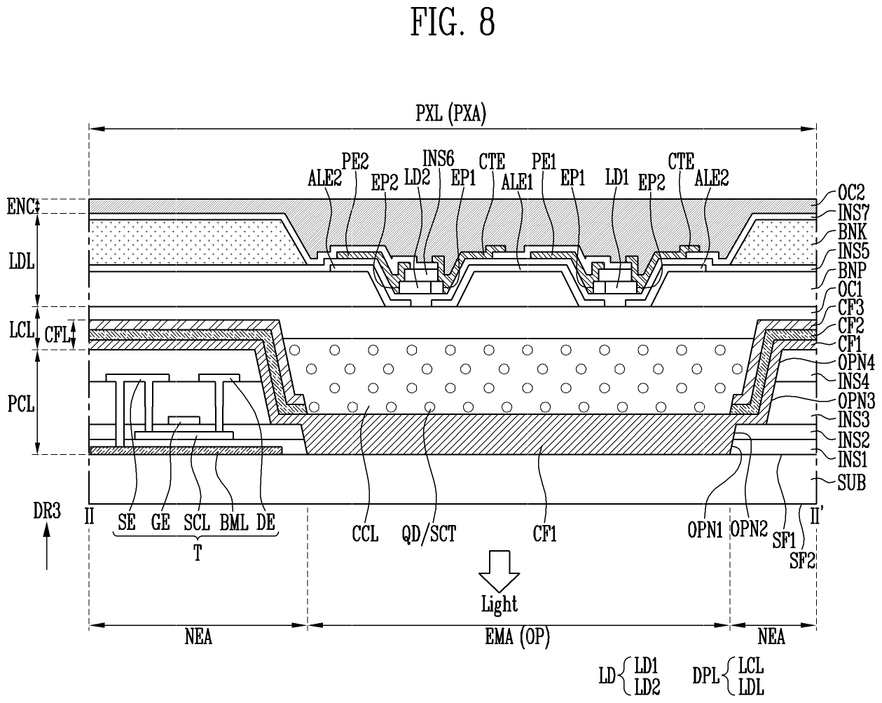

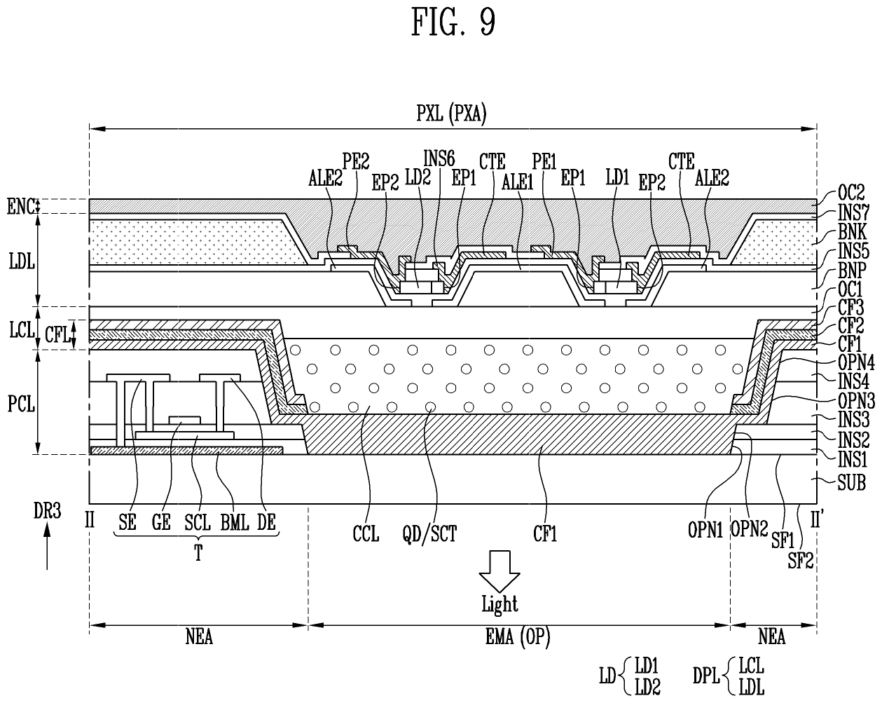

The embodiments of FIG. 8 and FIG. 9 illustrate variations of the embodiment of FIG. 7 with respect to the formation step of the first and second electrodes PE1 and PE2 and the intermediate electrode CTE and the presence or absence of a seventh insulating layer INS7. For example, FIG. 8 illustrates one or more embodiments in which the intermediate electrode CTE is formed after the first and second electrodes PE1 and PE2 and the seventh insulating layer INS7 are formed, and FIG. 9 illustrates one or more embodiments in which the first and second electrodes PE1 and PE2 are formed after the intermediate electrode CTE and the seventh insulating layer INS7 are formed.

In the embodiments of FIG. 7 to FIG. 11, the stacked structure (or the cross-sectional structure) of the pixel PXL is simplified and shown, such as showing each electrode only as an electrode of a single film, and each insulating layer only as an insulating layer of a single film, but is not limited thereto.

In relation to the embodiments of FIG. 7 to FIG. 11, differences from the above-described embodiment will be mainly described in order to avoid duplicate descriptions.

Referring to FIG. 1 to FIG. 11, the pixel PXL according to one or more embodiments may include the pixel circuit layer PCL, the display element layer DPL, and the encapsulation layer ENC disposed on the first surface SF1 of the substrate SUB.

The pixel circuit layer PCL and the display element layer DPL may be disposed to partially overlap each other on the first surface SF1 of the substrate SUB.

The substrate SUB may include a transparent insulating material to transmit light. The substrate SUB may be a rigid substrate or a flexible substrate. The substrate SUB may include the first surface SF1 (or the upper surface) and the second surface SF2 (or the lower surface) opposite each other in the third direction DR3. The second surface SF2 may be a display surface on which an image is displayed.

In each pixel area PXA of the pixel circuit layer PCL, circuit elements (for example, transistors T) configuring the pixel circuit PXC of the corresponding pixel PXL and suitable signal wires (e.g., predetermined signal wires) electrically connected to the circuit elements may be disposed.

In each pixel area PXA of the display element layer DPL, the light emitting element layer LDL configuring the emission component EMU of the corresponding pixel PXL, and the optical layer LCL that converts or transmits light emitted from the light emitting element layer LDL into light of a specific color, may be placed.

The pixel circuit layer PCL may include at least one insulating layer in addition to the circuit elements and the signal lines. For example, the pixel circuit layer PCL may include a first insulating layer INS1, a second insulating layer INS2, a third insulating layer INS3, and a fourth insulating layer INS4 sequentially stacked on the first surface SF1 of the substrate SUB along the third direction DR3.

The first insulating layer INS1 (or buffer layer) may be disposed on the first surface SF1 of the substrate SUB. The first insulating layer INS1 may reduce or prevent impurities from being diffused into the transistors T included in the pixel circuit PXC. The first insulating layer INS1 may be an inorganic insulating layer including an inorganic material. The first insulating layer INS1 may include at least one of a silicon nitride (SiNₓ), a silicon oxide (SiOₓ), and/or a silicon oxynitride (SiOₓN_{y}), or may include at least one of metal oxides such as an aluminum oxide (AlOₓ). The first insulating layer INS1 may be provided as a single film, and may be provided as a multi-layer of at least two or more films. In case that the first insulating layer INS1 is provided as the multi-film, respective layers thereof may be made of the same material or different materials. The first insulating layer INS1 may be omitted depending on the material, a process condition, and the like of the substrate SUB. In one or more embodiments, the first insulating layer INS1 may be partially opened to include a first opening OPN1 that at least exposes the first surface SF1 of the substrate SUB in the emission area EMA.

The second insulating layer INS2 (or gate insulating layer) may be entirely disposed on the first insulating layer INS1. The second insulating layer INS2 may include the same material as the first insulating layer INS1 described above, or may include a material suitable (or selected) from materials disclosed as constituent materials of the first insulating layer INS1. For example, the second insulating layer INS2 may be an inorganic insulating layer including an inorganic material. In one or more embodiments, the second insulating layer INS2 may be partially opened to at least expose the first surface SF1 of the substrate SUB in the emission area EMA. For example, the second insulating layer INS2 may be partially opened to include a second opening OPN2 corresponding to the first opening OPN1.

The third insulating layer INS3 (or interlayer insulating layer) may be entirely provided and/or formed on the second insulating layer INS2. The third insulating layer INS3 may include the same material as the first insulating layer INS1, or may include one or more materials suitable (or selected) from materials disclosed as constituent materials of the first insulating layer INS1. For example, the third insulating layer INS3 may be an inorganic insulating layer including an inorganic material. In one or more embodiments, the third insulating layer INS3 may be partially opened to include a third opening OPN3 that at least exposes the first surface SF1 of the substrate SUB in the emission area EMA. Both side surfaces of the third insulating layer INS3 with the third opening OPN3 interposed therebetween may be positioned outside of both side surfaces of the second insulating layer INS2 with the second opening OPN2 interposed therebetween. For example, both side surfaces of the third insulating layer INS3 may be positioned in the non-emission area NEA. However, the present disclosure is not limited thereto, and in one or more embodiments, both side surfaces of the second insulating layer INS2 with the second opening OPN2 interposed therebetween and both side surfaces of the third insulating layer INS3 with the third opening OPN3 interposed therebetween may be positioned on (or at) the same line.

The fourth insulating layer INS4 (or a passivation layer) may be entirely provided and/or formed on the third insulating layer INS3. The fourth insulating layer INS4 may include the same material as the first insulating layer INS1, or may include one or more materials suitable (or selected) from materials disclosed as constituent materials of the first insulating layer INS1. For example, the fourth insulating layer INS4 may be an inorganic insulating layer including an inorganic material. In one or more embodiments, the fourth insulating layer INS4 may be partially opened to at least expose the first surface SF1 of the substrate SUB in the emission area EMA. For example, the fourth insulating layer INS4 may be partially opened to include a fourth opening OPN4 corresponding to the third opening OPN3.

As described above, in the emission area EMA, the first surface SF1 of the substrate SUB may be at least exposed by the first opening OPN1 of the first insulating layer INS1, the second opening OPN2 of the second insulating layer INS2, the third opening OPN3 of the third insulating layer INS3, and the fourth opening OPN4 of the fourth insulating layer INS4. In one or more embodiments, both side surfaces of the first insulating layer INS1 with the first opening OPN1 interposed therebetween, both side surfaces of the second insulating layer INS2 with the second opening OPN2 interposed therebetween, both side surfaces of the third insulating layer INS3 with the third opening OPN3 interposed therebetween, and both side surfaces of the fourth insulating layer INS4 with the fourth opening OPN4 interposed therebetween may surround the emission area EMA. Both side surfaces of the first insulating layer INS1, both side surfaces of the second insulating layer INS2, both side surfaces of the third insulating layer INS3, and both side surfaces of the fourth insulating layer INS4, which are positioned near the emission area EMA, may have a step shape. As described above, due to the step shape of the first, second, third, and fourth insulating layers INS1, INS2, INS3, and INS4, a profile of a color filter layer CFL positioned in the emission area EMA may be smoothed.

The pixel circuit PXC may include at least one or more transistors T disposed on the first insulating layer INS1. The transistor T may include a driving transistor that controls a driving current of the light emitting element LD. The driving transistor may have the same configuration as the first transistor T1 described with reference to FIG. 5.

The transistor T is at least positioned in the non-emission area NEA, and may include a semiconductor pattern SCL, a gate electrode GE overlapping a portion of the semiconductor pattern SCL in the third direction DR3, and source and drain electrodes SE and DE electrically connected to the semiconductor pattern SCL.

The gate electrode GE may be provided and/or formed on the second insulating layer INS2. The gate electrode GE may overlap a portion of the semiconductor pattern SCL. For example, the gate electrode GE may overlap an active pattern of the semiconductor pattern SCL.

The semiconductor pattern SCL may be provided and/or formed on the first insulating layer INS1. For example, the semiconductor pattern SCL may be positioned between the first insulating layer INS1 and the second insulating layer INS2. The semiconductor pattern SCL may be made of a poly silicon, an amorphous silicon, an oxide semiconductor, or the like. The semiconductor pattern SCL may include an active pattern, a first contact area, and a second contact area. The active pattern, the first contact area, and the second contact area may be formed of a semiconductor layer in which an impurity is not doped or an impurity is doped. For example, the first contact area and the second contact area may be formed of a semiconductor layer doped with an impurity, and the active pattern may be formed of a semiconductor layer that is not doped with an impurity.

The active pattern of the semiconductor pattern SCL may be a channel area that is an area overlapping the gate electrode GE of the corresponding transistor T. The first contact area of the semiconductor pattern SCL may contact one end of the active pattern. In addition, the first contact area may be electrically connected to the source electrode SE. The second contact area of the semiconductor pattern SCL may contact the other end of the active pattern. In addition, the second contact area may be electrically connected to the drain electrode DE.

The source electrode SE may be provided and/or formed on the third insulating layer INS3. The source electrode SE may contact the first contact area of the semiconductor pattern SCL through a contact hole penetrating the second insulating layer INS2 and the third insulating layer INS3.

The drain electrode DE may be provided and/or formed on the third insulating layer INS3. The drain electrode DE may be disposed to be spaced from the source electrode SE on the third insulating layer INS3. The drain electrode DE may contact the second contact area of the semiconductor pattern SCL through a contact hole penetrating the second insulating layer INS2 and the third insulating layer INS3.

A lower metal pattern BML may be disposed under the transistor T1.

The lower metal pattern BML may be a first conductive layer positioned between the first surface SF1 of the substrate SUB and the first insulating layer INS1. The lower metal pattern BML may be electrically connected to the source electrode SE of the transistor T through a contact hole sequentially passing through the third insulating layer INS3, the second insulating layer INS2, and the first insulating layer INS1. In this case, a driving range of a suitable voltage (e.g., a predetermined voltage) supplied to the gate electrode GE of the transistor T may be widened. The lower metal pattern BML may be electrically connected to the source electrode SE to stabilize a channel area of the transistor T. In addition, as the bottom metal pattern BML is electrically connected to the transistor T, floating of the lower metal pattern BML may be prevented.

The bottom metal pattern BML may be formed to have a single layer structure of a single or a mixture thereof selected from a group consisting of copper (Cu), molybdenum (Mo), tungsten (W), aluminum neodymium (AlNd), titanium (Ti), aluminum (Al), silver (Ag), and an alloy thereof, or in order to reduce line resistance, it may be formed to have a double layer or multi-layer structure of molybdenum (Mo), titanium (Ti), copper (Cu), aluminum (Al) or silver (Ag), which are a low-resistance material.

In one or more embodiments, the lower metal pattern BML may be at least positioned between the first surface SF1 of the substrate SUB and the first insulating layer INS1 in the non-emission area NEA, and may overlap the transistor T positioned thereon to have an expanded (or extended) shape to be able to sufficiently cover the transistor T. The lower metal pattern BML may be used as a light blocking member for protecting the transistor T by blocking light that may be incident from the second surface SF2 of the substrate SUB. For this purpose, the lower metal pattern BML may be made of light blocking and/or light absorbing materials. For example, the lower metal pattern BML may be configured as an opaque metal layer. The lower metal pattern BML may be disposed only in the non-emission area NEA.

The first insulating layer INS1 may be disposed on the lower metal pattern BML described above. The first insulating layer INS1 may cover the lower metal pattern BML in the non-emission area NEA to protect the lower metal pattern BML.

In the above-described embodiment, the case in which the transistor T is a thin film transistor (TFT) having a top gate structure is described as an example, but the present disclosure is not limited thereto, and the structure of the transistor T may be variously changed.

The pixel circuit layer PCL may include a suitable power line (e.g., a predetermined power line) disposed on the third insulating layer INS3. For example, the pixel circuit layer PCL may include the second power line PL2 disposed on the third insulating layer INS3. A voltage of the second driving power source VSS may be applied to the second power line PL2. The pixel circuit layer PCL may further include the first power line PL1 described with reference to FIG. 5. The first power line PL1 may be formed by the same process as that of the second power line PL2 to be provided on (or at) the same layer as that of the second power line PL2, or may be formed by a different process from that of the second power line PL2 to be provided on a different layer from that of the second power line PL2. However, the present disclosure is not limited thereto.

The above-described first and second power lines PL1 and PL2 may be positioned in the non-emission area NEA while at least bypassing the emission area EMA. In case that the first and second power lines PL1 and PL2 are made of an opaque metal, the first and second power lines PL1 and PL2 may be used as light blocking members that block light incident from the second surface SF2 of the substrate SUB together with the lower metal pattern BML.

The fourth insulating layer INS4 may be disposed on the transistor T and the second power line PL2.

The display element layer DPL may be disposed on the fourth insulating layer INS4. In one or more embodiments, the display element layer DPL may include the optical layer LCL and the light emitting element layer LDL.

The optical layer LCL may include a color filter layer CFL, a color conversion layer CCL, and a first overcoat layer OC1.

Components that selectively transmit light emitted from the color conversion layer CCL to the second surface SF2 of the substrate SUB may be disposed on the color filter layer CFL. For example, the color filter layer CFL may at least include a color filter corresponding to the emission area EMA. For example, the color filter layer CFL may include a first color filter CF1 disposed under the color conversion layer CCL of one pixel PXL (hereinafter referred to as a “first pixel”), a second color filter CF2 disposed under the color conversion layer of a pixel (hereinafter referred to as a “second pixel”) adjacent to the first pixel PXL, and a third color filter CF3 disposed under the color conversion layer of a pixel (hereinafter referred to as a “third pixel”) adjacent to the second pixel.

The first color filter CF1 may be directly disposed on the first surface SF1 of the substrate SUB in at least the emission area EMA, and is disposed on the fourth insulating layer INS4 in at least the non-emission area NEA. In addition, the first color filter CF1 may be disposed on both side surfaces of the first insulating layer INS1 with the first opening OPN1 therebetween, both side surfaces of the second insulating layer INS2 with the second opening OPN2 therebetween, both side surfaces of the third insulating layer INS3 with the third opening OPN3 therebetween, and both side surfaces of the fourth insulating layer INS4 with the fourth opening OPN4 therebetween.

The first, second, and third color filters CF1, CF2, and CF3 may be disposed to overlap each other in the non-emission area NEA to be used as a light blocking member to block light interference between adjacent pixels PXL. In addition, the first, second, and third color filters CF1, CF2, and CF3 disposed to overlap each other in the non-emission area NEA surround the emission area EMA of the pixel PXL, and may configure a dam structure DAM that finally defines the emission area EMA by defining a position to which the color conversion layer CCL is to be supplied. The dam structure DAM is positioned on the first, second, third, and fourth insulating layers INS1, INS2, INS3, and INS4 in the non-emission area NEA, and may surround the emission area EMA.

The color conversion layer CCL may be formed on the first color filter CF1 in the emission area EMA surrounded by the dam structure DAM. The color conversion layer CCL may include color conversion particles QD corresponding to a specific color. For example, the color conversion layer CCL may include the color conversion particles QD that convert light of a first color emitted from the light emitting elements LD into light (“light of a specific color” or “light with excellent color reproduction”) of a second color.

In case that the pixel PXL is a red pixel (or red sub-pixel), the color conversion layer CCL of the pixel PXL may include the color conversion particles QD of red quantum dots that converts the light of the first color emitted from the light emitting elements LD into the light of the second color (for example, light of a red color). In case that the pixel PXL is a red pixel (or red sub-pixel), the first color filter CF1 may be a red color filter, one of the second and third color filters CF2 and CF3 may be a green color filter, and the other thereof may be a blue color filter.

In case that the pixel PXL is a green pixel (or green sub-pixel), the color conversion layer CCL of the pixel PXL may include the color conversion particles QD of green quantum dots that converts the light of the first color emitted from the light emitting elements LD into the light of the second color (for example, light of a green color). In case that the pixel PXL is a green pixel (or green sub-pixel), the first color filter CF1 may be a green color filter, one of the second and third color filters CF2 and CF3 may be a red color filter, and the other thereof may be a blue color filter.

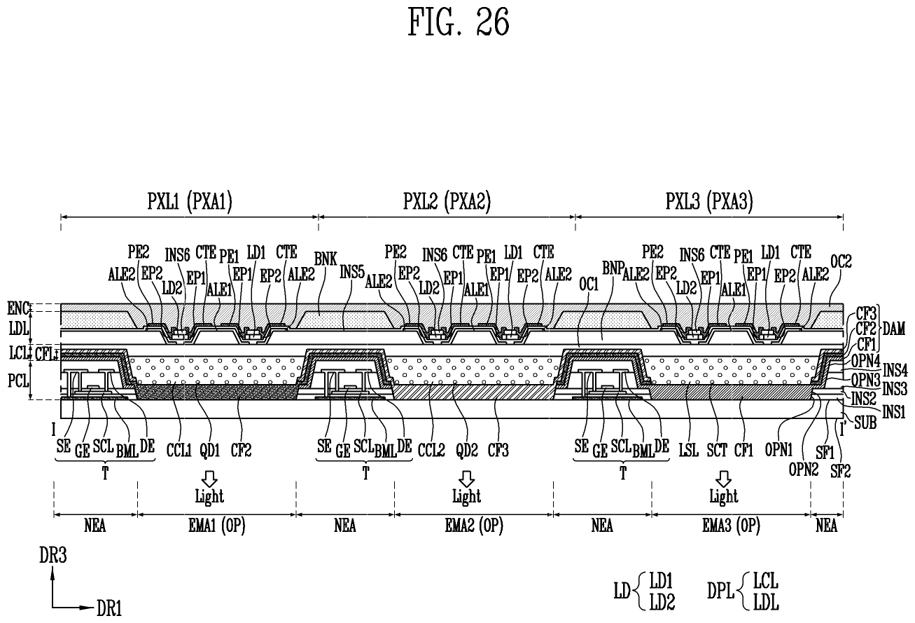

In case that the pixel PXL is a blue pixel (or blue sub-pixel), the color conversion layer CCL of the pixel PXL may include the color conversion particles QD of blue quantum dots that converts the light of the first color emitted from the light emitting elements LD into the light of the second color (for example, light of a blue color). In case that the pixel PXL is a blue pixel (or blue sub-pixel), in one or more embodiments, a light scattering layer (refer to “LSL” in FIG. 26) including light scattering particles SCT may be provided instead of the color conversion layer CCL including the color conversion particles QD. For example, in case that the light emitting elements LD emits blue light, the pixel PXL may include the light scattering layer LSL including the light scattering particles SCT. The above-described light scattering layer LSL may be omitted according to one or more embodiments.

According to one or more embodiments, when the pixel PXL is the blue pixel (or blue sub-pixel), a transparent polymer may be provided instead of the color conversion layer CCL. In case that the pixel PXL is a blue pixel (or blue sub-pixel), the first color filter CF1 may be a blue color filter, one of the second and third color filters CF2 and CF3 may be a red color filter, and the other thereof may be a green color filter.

The first overcoat layer OC1 may be entirely disposed on the color filter layer CFL and the color conversion layer CCL. The first overcoat layer OC1 may be used as a planarization layer that alleviates a step formed by the color filter layer CFL and the color conversion layer CCL positioned thereunder in the optical layer LCL. The first overcoat layer OC1 may include an insulating material that transmits light. For example, the first overcoat layer OC1 may be an organic insulating layer including an organic material. Accordingly, the first overcoat layer OC1 may have a thickness equal to or greater than a certain level, and may have a flat surface. In this case, a step coverage of components (or upper members) to be disposed on the first overcoat layer OC1 may be improved. The light emitting element layer LDL may be provided and/or formed on the first overcoat layer OC1.

Components involved in aligning and driving the light emitting elements LD may be disposed on the light emitting element layer LDL.

The light emitting element layer LDL may include bank patterns BNP, the alignment electrodes ALE, the bank BNK, the light emitting elements LD, the electrodes PE, and/or the intermediate electrode CTE.

The bank patterns BNP may be positioned on the first overcoat layer OC1. For example, the bank patterns BNP may protrude in the third direction DR3 on one surface of the first overcoat layer OC1. Accordingly, one area of the alignment electrodes ALE disposed on the bank patterns BNP may protrude in the third direction DR3 (or the thickness direction of the substrate SUB).

The bank patterns BNP may include an inorganic insulating layer including an inorganic material or an organic insulating layer including an organic material. In one or more embodiments, the bank pattern BNP may include an organic insulating layer of a single layer and/or an inorganic insulating layer of a single layer, but is not limited thereto. In one or more embodiments, the bank pattern BNP may be provided in a multi-layered structure in which at least one or more of organic insulating layer and at least one or more of inorganic insulating layer are stacked. However, the material of the bank pattern BNP is not limited to the above-described example, and in one or more embodiments, the bank pattern BNP may include a conductive material (or substance).

The bank pattern BNP may have cross-sections of a trapezoidal shape of which width is narrowed from a surface (for example, an upper surface) of the first overcoat layer OC1 toward an upper portion thereof along the third direction DR3, but is not limited thereto. In addition, in one or more embodiments, at least one of the bank pattern BNP may be omitted, or the position thereof may be changed. In addition, in one or more embodiments, the bank pattern BNP may be omitted.

In one or more embodiments, the bank pattern BNP may include a transparent insulating material to reduce or minimize loss of light emitted from the light emitting element LD to be directed toward an image display direction of the display device DD (for example, the second surface SF2 of the substrate SUB).

The alignment electrodes ALE may be positioned on the bank pattern BNP.

The alignment electrodes ALE may be disposed on (or at) the same plane, and may have the same thickness in the third direction DR3. The alignment electrodes ALE may be concurrently (e.g., simultaneously) formed in the same process.

The alignment electrodes ALE may be formed of a transparent conductive material to reduce or minimize loss of light emitted from the light emitting elements LD to be directed in the image display direction of the display device DD (or the second surface SF2 direction of the substrate SUB). The transparent conductive material (or substance) may include a conductive oxide such as an indium tin oxide (ITO), an indium zinc oxide (IZO), a zinc oxide (ZnOₓ), an indium gallium zinc oxide (IGZO), and/or an indium tin zinc oxide (ITZO), and/or a conductive polymer such as poly(3,4-ethylenedioxythiophene) (PEDOT).

The alignment electrodes ALE may include the second alignment electrode ALE2, the first alignment electrode ALE1, and another second alignment electrode ALE2 disposed to be spaced from each other.

The another second alignment electrode ALE2 may be electrically connected to some components of the pixel circuit layer PCL, for example, the second power line PL2 through the first via hole VIH1 sequentially passing through the first overcoat layer OC1, the color filter layer CFL, and the fourth insulating layer INS4 in at least the non-emission area NEA. The color filter layer CFL may include the first, second, and third color filters CF1, CF2, and CF3 sequentially stacked along the third direction DR3 from one surface of the fourth insulating layer INS4.

In one or more embodiments, the first alignment electrode ALE1 may be electrically connected to some components of the pixel circuit layer PCL, for example, the upper electrode (UE) of the storage capacitor Cst through the second via hole VIH2 sequentially passing through the first overcoat layer OC1, the color filter layer CFL, and the fourth insulating layer INS4 in at least the non-emission area NEA.

The fifth insulating layer INS5 may be provided and/or formed on the alignment electrodes ALE.

The fifth insulating layer INS5 may be disposed on the alignment electrodes ALE and the first overcoat layer OC1. The fifth insulating layer INS5 may be partially opened to expose components positioned thereunder in at least the non-emission area NEA. For example, the fifth insulating layer INS5 may be partially opened to include the first contact hole CH1 exposing a portion of the first alignment electrode ALE1 by removing one area from at least the non-emission area NEA and the second contact hole CH2 exposing a portion of the second alignment electrode ALE2 by removing another area from the at least the non-emission area NEA.

The fifth insulating layer INS5 may be formed as an inorganic insulating layer made of an inorganic material. The fifth insulating layer INS5 may be provided as a single layer or multi-layer. When the fifth insulating layer INS5 is provided as a multi-film, the fifth insulating layer INS5 may be provided in a distributed Bragg reflector structure in which a first layer and a second layer having different refractive indexes are alternately stacked.

The bank BNK may be positioned on the fifth insulating layer INS5.

The bank BNK may be disposed on the fifth insulating layer INS5 in at least the non-emission area NEA, but is not limited thereto. The bank BNK may be a structure defining (or partitioning) supply positions of the light emitting elements LD.

The bank BNK and the bank pattern BNP described above may be formed by different processes to be provided on different layers, but are not limited thereto. In one or more embodiments, the bank BNK and the bank pattern BNP may be formed by different processes and provided on the same layer, or may be formed by the same process and provided on the same layer.

In the emission area EMA of the pixel PXL in which the fifth insulating layer INS5 and the bank BNK are formed, the light emitting elements LD may be supplied and aligned. For example, the light emitting elements LD are supplied (or inputted) to the emission area EMA through an inkjet printing method or the like, and the light emitting elements LD may be aligned between the alignment electrodes ALE by an electric field formed by an alignment signal applied to each of the alignment electrodes ALE. For example, the light emitting elements LD may be aligned on the fifth insulating layer INS5 between the first alignment electrode ALE1 and the second alignment electrode ALE2.

The light emitting elements LD may include the first light emitting element LD1 and the second light emitting element LD2.

The first light emitting element LD1 may be arranged between one side (or the right side) of the first alignment electrode ALE1 and another second alignment electrode ALE2 adjacent to one side of the first alignment electrode ALE1. The first light emitting element LD1 may include the first end portion EP1 overlapping the first alignment electrode ALE1 and the second end portion EP2 overlapping the another second alignment electrode ALE2.

The second light emitting element LD2 may be arranged between the other side (or the left side) of the first alignment electrode ALE1 and the second alignment electrode ALE2 adjacent to the other side of the first alignment electrode ALE1. The second light emitting element LD2 may include the first end portion EP1 overlapping the first alignment electrode ALE1 and the second end portion EP2 overlapping the second alignment electrode ALE2.

A sixth insulating layer INS6 (or an insulating pattern) may be disposed on the first and second light emitting elements LD1 and LD2, respectively. The sixth insulating layer INS6 may be positioned on the first and second light emitting elements LD1 and LD2 to partially cover an outer surface(e.g., an outer peripheral or circumferential surface or a surface) of each of the first and second light emitting elements LD1 and LD2 to expose the first end portion EP1 and the second end portion EP2 of each of the first and second light emitting elements LD1 and LD2 to the outside.

The sixth insulating layer INS6 may include an inorganic insulating layer including an inorganic material or an organic insulating film. For example, the sixth insulating layer INS6 may include an inorganic insulating layer that is suitable for protecting the active layer 12 of each of the first and second light emitting elements LD1 and LD2 from external oxygen and moisture. However, the present disclosure is not limited thereto, and the sixth insulating layer INS6 may be configured as an organic insulating layer including an organic material depending on the design condition of the display device DD (or the display panel DP) to which the first and second light emitting elements LD1 and LD2 are applied. The sixth insulating layer INS6 may be configured as a single layer or a multi-layer.

In case that an empty gap exists between the first and second light emitting elements LD1 and LD2 and the fifth insulating layer INS5 before the sixth insulating layer INS6 is formed, the empty gap may be filled with the sixth insulating layer INS6 in the process of forming the sixth insulating layer INS6.

By forming the sixth insulating layer INS6 on the aligned light emitting elements LD in the emission area EMA of each pixel PXL, it is possible to prevent the light emitting elements LD from deviating separated from their aligned position.

On the first and second end portions EP1 and EP2 of the light emitting elements LD not covered by the sixth insulating layer INS6, different electrodes from among the first electrode PE1, the second electrode PE2, and the intermediate electrode CTE may be formed. For example, the first electrode PE1 may be formed on the first end portion EP1 of the first light emitting element LD1, the intermediate electrode CTE may be formed on the second end portion EP2 of the first light emitting element LD1, the intermediate electrode CTE may be formed on the first end portion EP1 of the second light emitting element LD2, and the second electrode PE2 may be formed on the second end portion EP2 of the second light emitting element LD2.

The first electrode PE1 may be disposed at the upper portion of the first alignment electrode ALE1 to overlap the right side of the first alignment electrode ALE1, and the second electrode PE2 may be disposed at the upper portion of the second alignment electrode ALE2 to overlap the second alignment electrode ALE2 adjacent to the left side of the first alignment electrode ALE1. The intermediate electrode CTE may be disposed at the upper portion of each of the other second alignment electrodes ALE2 adjacent to the right side of the first alignment electrode ALE1 and the left side of the first alignment electrode ALE1.

The first electrode PE1 may be electrically connected to the first alignment electrode ALE1 through the first contact hole CH1 of the fifth insulating layer INS5, and the second electrode PE2 may be electrically connected to the second alignment electrode ALE2 through the second contact hole CH2 of the fifth insulating layer INS5.

In one or more embodiments, the first electrode PE1, the intermediate electrode CTE, and the second electrode PE2 may be formed on (or at) the same layer or different layers. For example, the mutual positions and/or the formation order of the first electrode PE1, the intermediate electrode CTE, and the second electrode PE2 may be variously changed according to embodiments.

In the embodiment of FIG. 7, the first electrode PE1, the second electrode PE2, and the intermediate electrode CTE may be concurrently (e.g., simultaneously) formed with the corresponding sixth insulating layer INS6 therebetween. For example, the first electrode PE1 may be positioned adjacent to one side surface (for example, the left side surface) of the sixth insulating layer INS6 on the first light emitting element LD1, and the intermediate electrode CTE may be positioned adjacent to the other side surface (for example, the right side surface) of the sixth insulating layer INS6. The second electrode PE2 may be positioned adjacent to one side surface (for example, the left side surface) of the sixth insulating layer INS6 of the second light emitting element LD2, and the intermediate electrode CTE may be positioned adjacent to the other side surface (for example, the right side surface) of the sixth insulating layer INS6. The first electrode PE1 may directly contact the first end portion EP1 of the first light emitting element LD1 to be electrically connected to the first light emitting element LD1. The intermediate electrode CTE may directly contact each of the second end portion EP2 of the first light emitting element LD1 and the first end portion EP1 of the second light emitting element LD2 to be electrically connected to each of the first and second light emitting elements LD1 and LD2. The second electrode PE2 may directly contact the second end portion EP2 of the second light emitting element LD2 to be electrically connected to the second light emitting element LD2. In the embodiment of FIG. 7, in case that the first electrode PE1, the second electrode PE2, and the intermediate electrode CTE are disposed on (or at) the same layer and formed at the same time, the manufacturing process of the pixel PXL (or the display device DD) may be simplified, and manufacturing efficiency may be improved.

In the embodiment of FIG. 8, the first and second electrodes PE1 and PE2 may be first formed on the sixth insulating layer INS6. The first electrode PE1 may directly contact the first end portion EP1 of the first light emitting element LD1 to be electrically connected to the first light emitting element LD1. The second electrode PE2 may directly contact the second end portion EP2 of the second light emitting element LD2 to be electrically connected to the second light emitting element LD2. Thereafter, the seventh insulating layer INS7 may be formed to cover the first and second electrodes PE1 and PE2.

The seventh insulating layer INS7 may be positioned on the first and second electrodes PE1 and PE2 to cover the first and second electrodes PE1 and PE2 (or to not expose the first and second electrodes PE1 and PE2 to the outside), thereby protecting the first and second electrodes PE1 and PE2.

The seventh insulating layer INS7 may include an inorganic insulating layer made of an inorganic material or an organic insulating layer made of an organic material. In addition, the seventh insulating layer INS7 may be formed as a single layer or a multilayer.

The intermediate electrode CTE may be formed on the seventh insulating layer INS7. The intermediate electrode CTE may be electrically connected between the first light emitting element LD1 and the second light emitting element LD2 by directly contacting the second end portion EP2 of the first light emitting element LD1 and the first end portion EP1 of the second light emitting element LD2.

In the embodiments of FIG. 9, the intermediate electrode CTE may be first formed on the sixth insulating layer INS6. Thereafter, the seventh insulating layer INS7 is formed to cover the intermediate electrode CTE, and the first and second electrodes PE1 and PE2 may be formed in the emission area EMA in which the seventh insulating layer INS7 is formed.

As in the embodiments of FIG. 8 and FIG. 9, in case that the electrodes disposed on the first end portion EP1 and the second end portion EP2 of each light emitting element LD are disposed on different layers, because the electrodes may be stably and electrically separated, electrical stability between the first and second end portions EP1 and EP2 of the light emitting elements LD may be secured.

The first electrode PE1, the second electrode PE2, and the intermediate electrode CTE may be made of a material having a reflectance in order to allow the light emitted from the light emitting elements LD to be directed in the image display direction of the display device DD (for example, the “rear direction” or “second surface SF2 direction of the substrate SUB”). For example, each of the first electrode PE1, the second electrode PE2, and the intermediate electrode CTE may be made of a conductive material (or substance). The conductive material may include an opaque metal that is suitable for reflecting light emitted by the light emitting elements LD in the second surface SF2 direction of the substrate SUB. The opaque metal may include, for example, silver (Ag), magnesium (Mg), aluminum (Al), platinum (Pt), palladium (Pd), gold (Au), nickel (Ni), neodymium (Nd), iridium (Ir), chromium (Cr), titanium (Ti), and/or an alloy thereof. However, the material of each of the first electrode PE1, the second electrode PE2, and the intermediate electrode CTE is not limited to the above-described embodiment. In one or more embodiments, each of the first electrode PE1, the second electrode PE2, and the intermediate electrode CTE may include a transparent conductive material (or substance). The transparent conductive material (or substance) may include a conductive oxide such as an indium tin oxide (ITO), an indium zinc oxide (IZO), a zinc oxide (ZnOₓ), an indium gallium zinc oxide (IGZO), and/or an indium tin zinc oxide (ITZO), and/or a conductive polymer such as poly(3,4-ethylenedioxythiophene) (PEDOT). As described above, in case that each of the first electrode PE1, the second electrode PE2, and the intermediate electrode CTE may include a transparent conductive material (or substance), a separate conductive layer made of an opaque metal for reflecting the light emitted from the light emitting elements LD in the direction of the second surface SF2 of the substrate SUB may be added. However, the material of each of the first electrode PE1, the second electrode PE2, and the intermediate electrode CTE is not limited to the above-described materials.

In one or more embodiments, each of the first electrode PE1, the second electrode PE2, and the intermediate electrode CTE may be a reflective member that guides (or reflects) the light emitted from the light emitting elements LD in the direction of the second surface SF2 of the substrate SUB.

The encapsulation layer ENC may be provided and/or formed on the above-described light emitting element layer LDL.

The encapsulation layer ENC may include the second overcoat layer OC2. The second overcoat layer OC2 may block water or moisture from flowing into the display element layer DPL from the outside by entirely covering components positioned thereunder. In one or more embodiments, the second overcoat layer OC2 may be used as a planarization layer that alleviates a step caused by components of the display element layer DPL positioned thereunder. In one or more embodiments, the second overcoat layer OC2 may be positioned on the light emitting element layer LDL to protect the light emitting element layer LDL and block light flowing in from the outside, thereby preventing components positioned thereunder from being viewed. In addition, the second overcoat layer OC2 may prevent light leakage of some light that may be emitted between two electrodes (for example, the first electrode PE1 and the intermediate electrode CTE, the intermediate electrode CTE and the second electrode PE2) spaced from each other with the sixth insulating layer INS6 therebetween. The second overcoat layer OC2 may be made of a light blocking and/or light absorbing material. For example, the second overcoat layer OC2 may be configured of a black matrix, but is not limited thereto.

According to the above-described embodiments, a portion of each of the first, second, third, and fourth insulating layers INS1, INS2, INS3, and INS4 included in the pixel circuit layer PCL is removed to form the first, second, third, and fourth openings OPN1, OPN2, OPN3, and OPN4, and the first surface SF1 of the substrate SUB corresponding to the openings may be exposed in at least the emission area EMA to continuously form the optical layer LCL on the exposed first surface SF1 of the substrate SUB. In this case, the process of forming the optical layer LCL on the light emitting element layer LDL is omitted, so the manufacturing efficiency of the display device DD may be improved. In addition, the manufacturing cost of the display device DD may be reduced.

According to the above-described embodiments, by improving the step coverage of the light emitting element layer LDL formed on the first overcoat layer OC1 by disposing the first overcoat layer OC1 having a flat surface on the color filter layer CFL and the color conversion layer CCL, reliability of the display device DD may be further improved.

According to the above-described embodiments, by disposing the optical layer LCL between the pixel circuit layer PCL and the light emitting element layer LDL, it is possible to block an electric field induced from the pixel circuit PXC included in the pixel circuit layer PCL from affecting the alignment and/or driving of light emitting elements LD.

According to the above-described embodiments, by disposing the lower metal pattern BML having a size sufficient to sufficiently cover the transistor T between the first surface SF1 of the substrate SUB and the first insulating layer INS1 in at least the non-emission area NEA, it is possible to block light incident from the second surface SF2 of the substrate SUB, and to prevent light emitted from adjacent pixels PXL from being mixed.

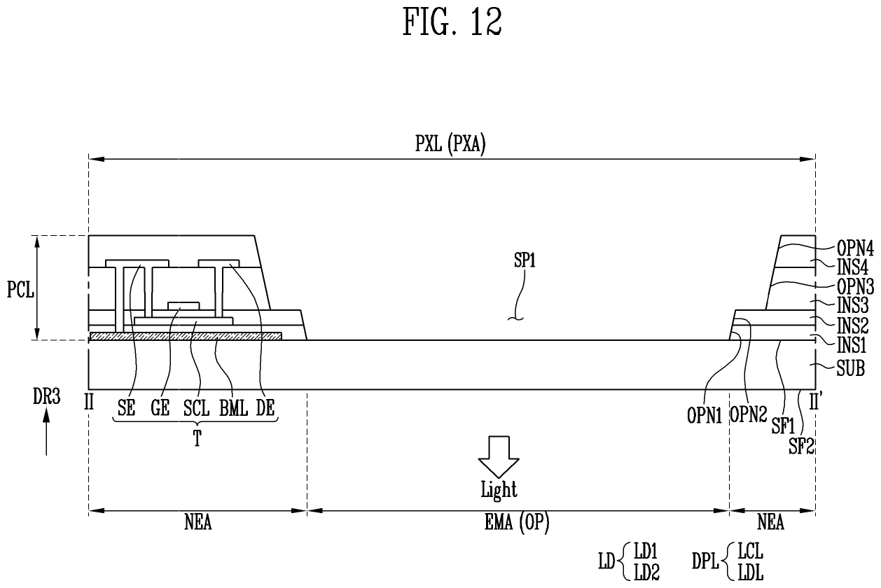

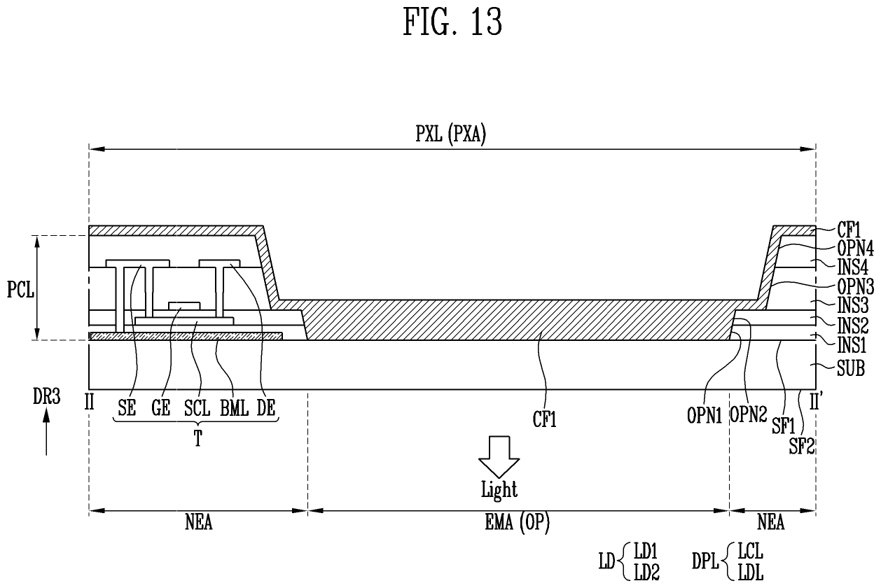

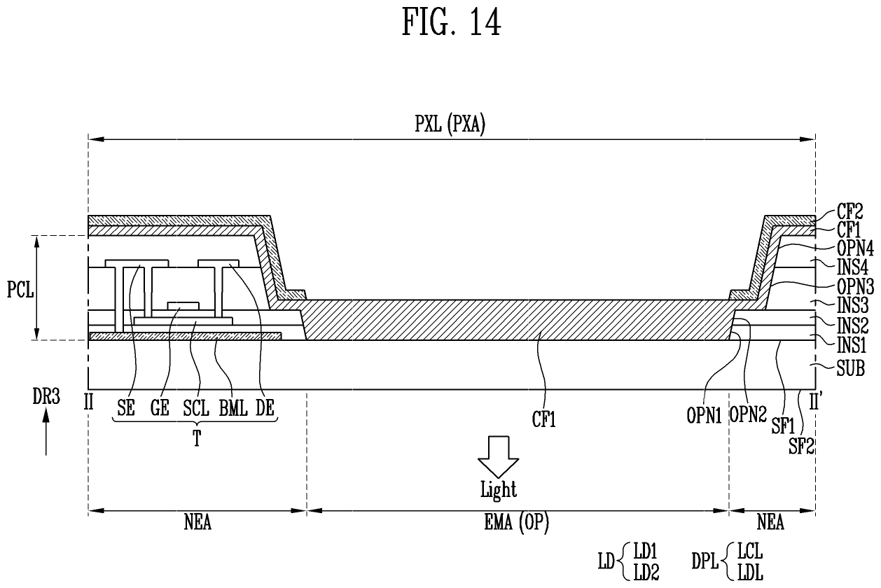

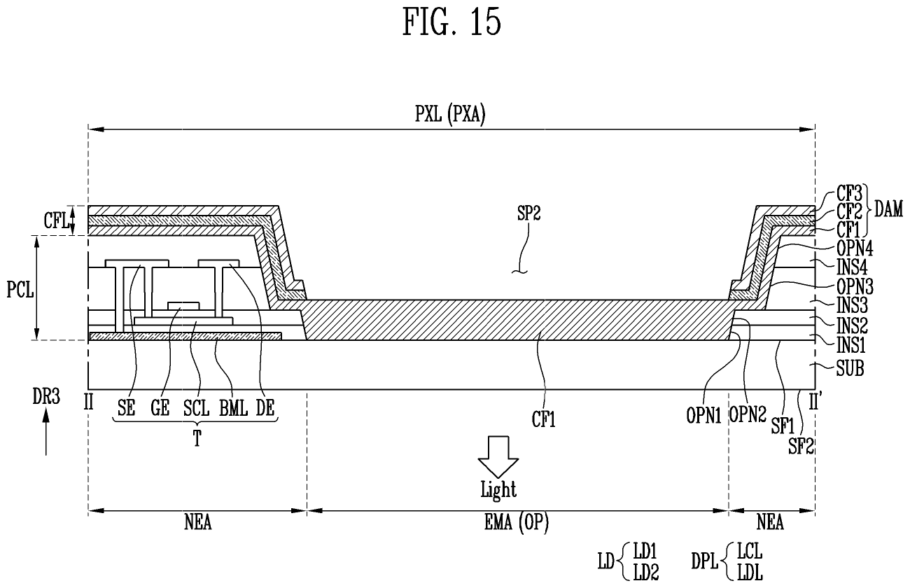

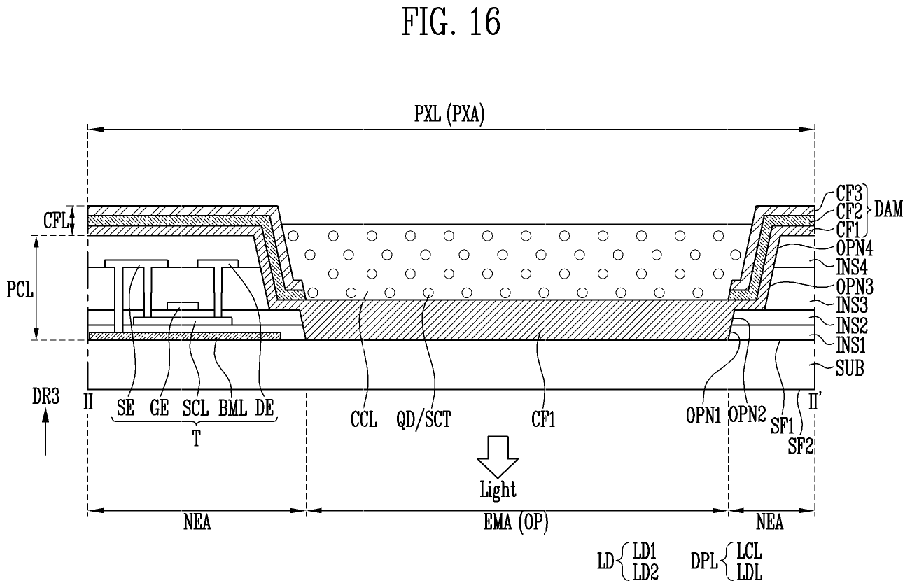

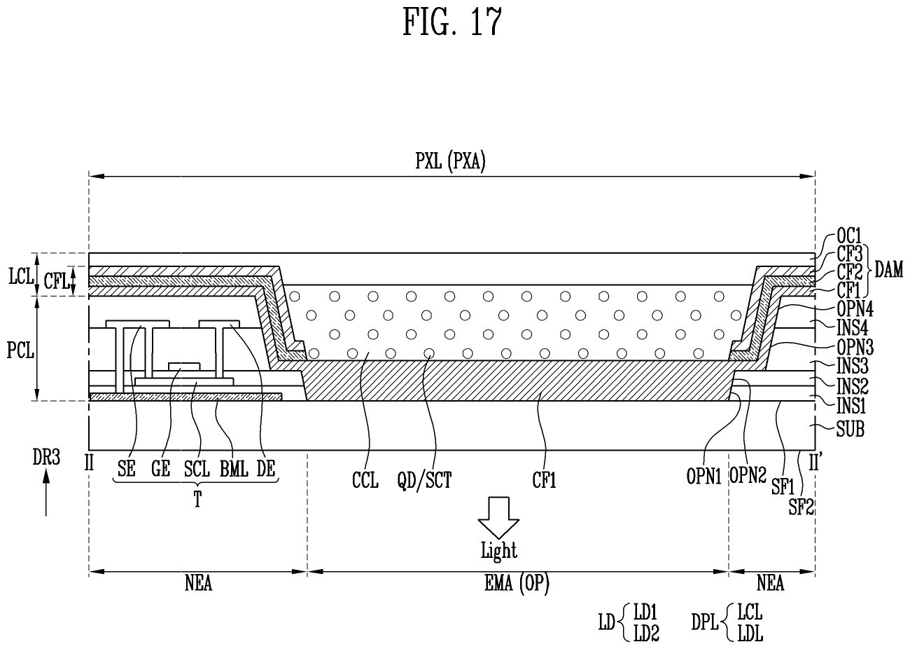

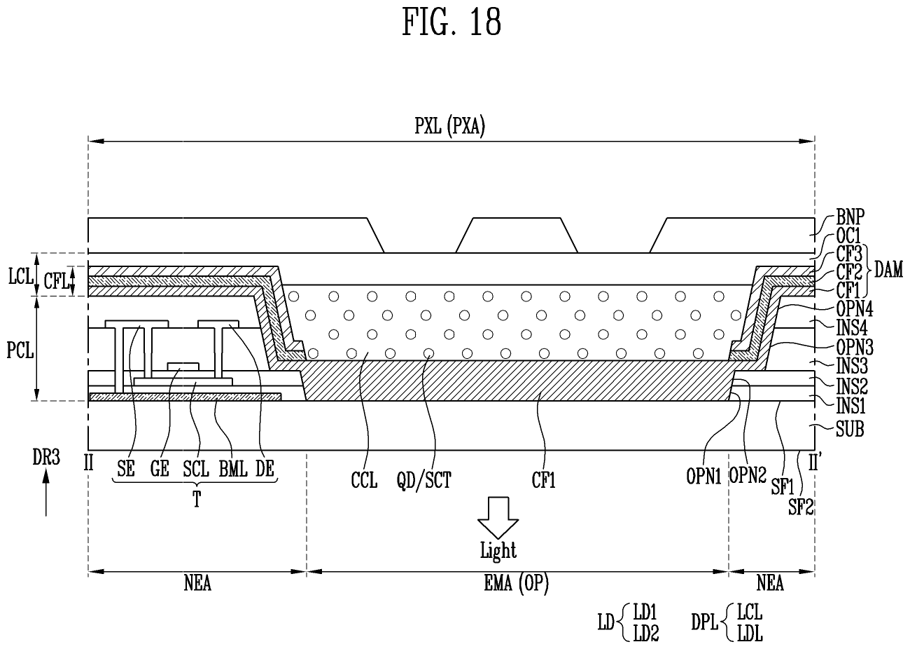

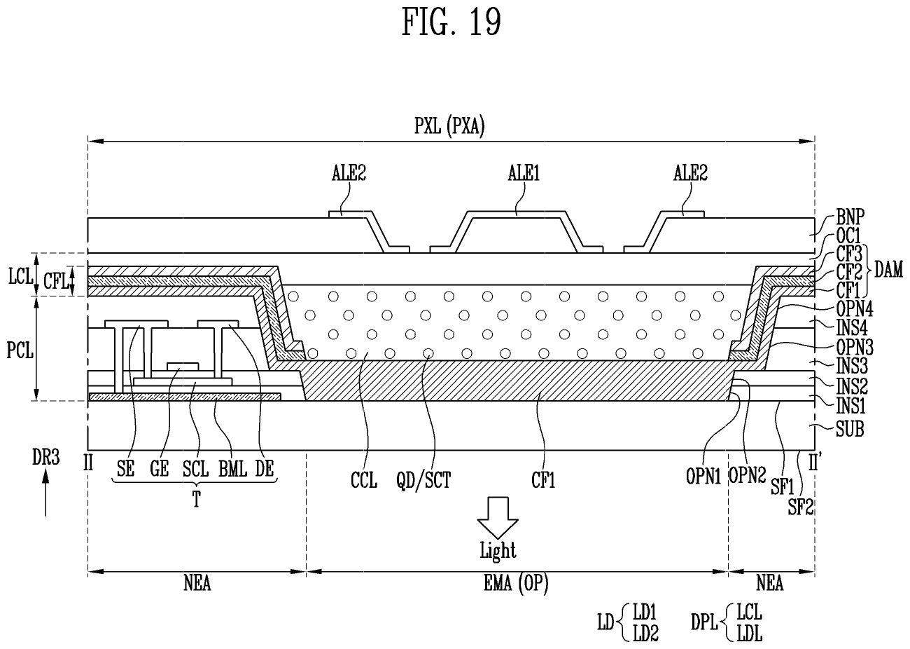

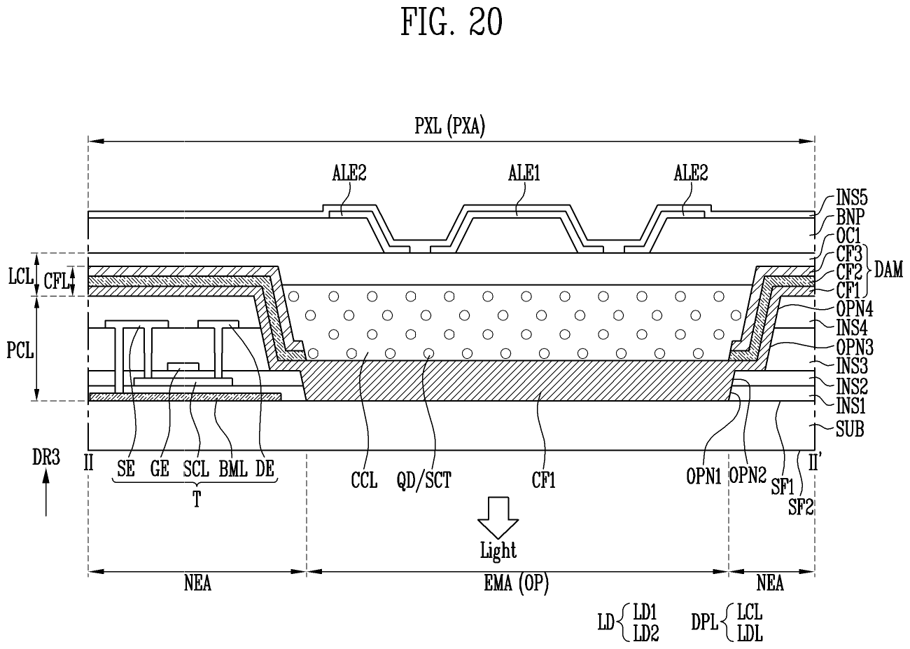

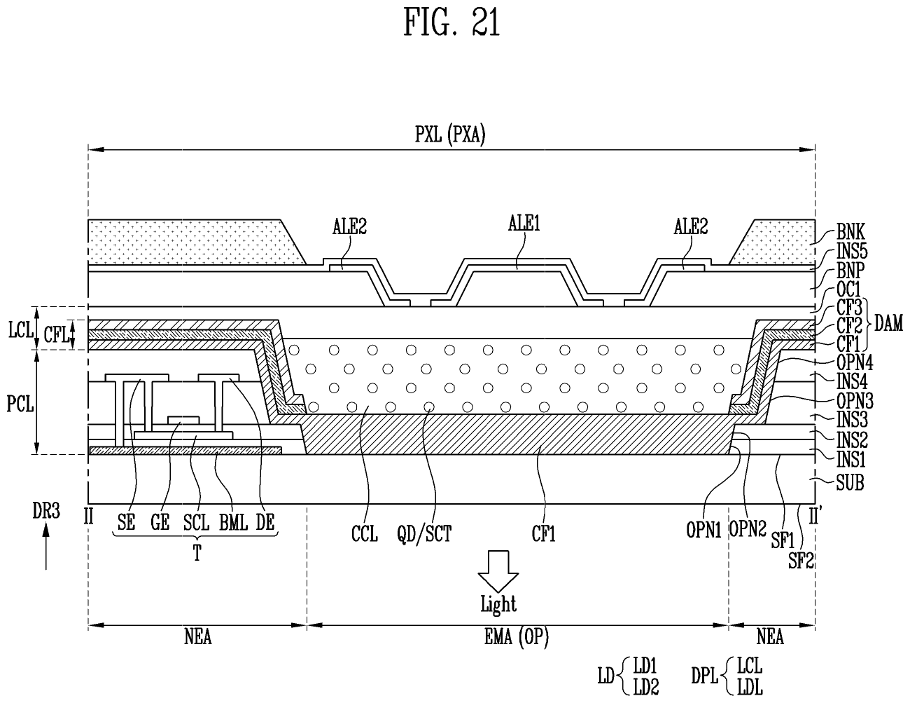

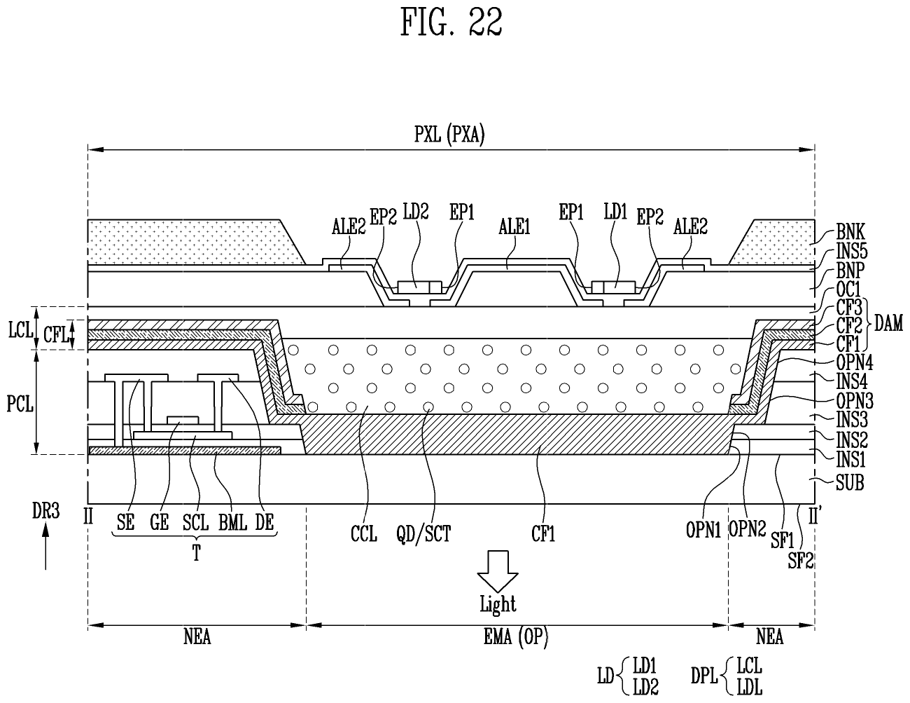

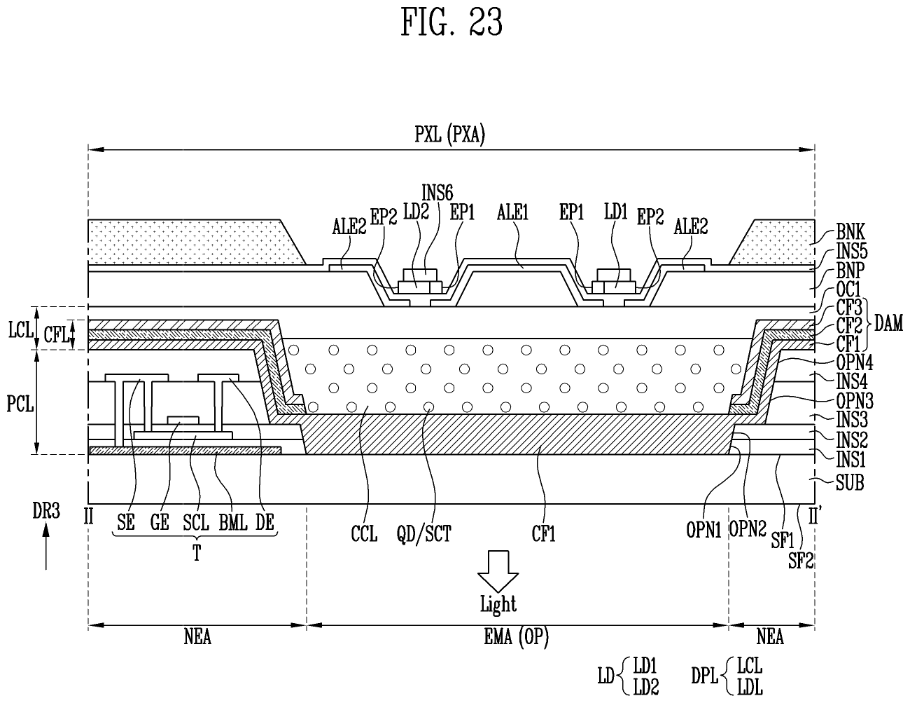

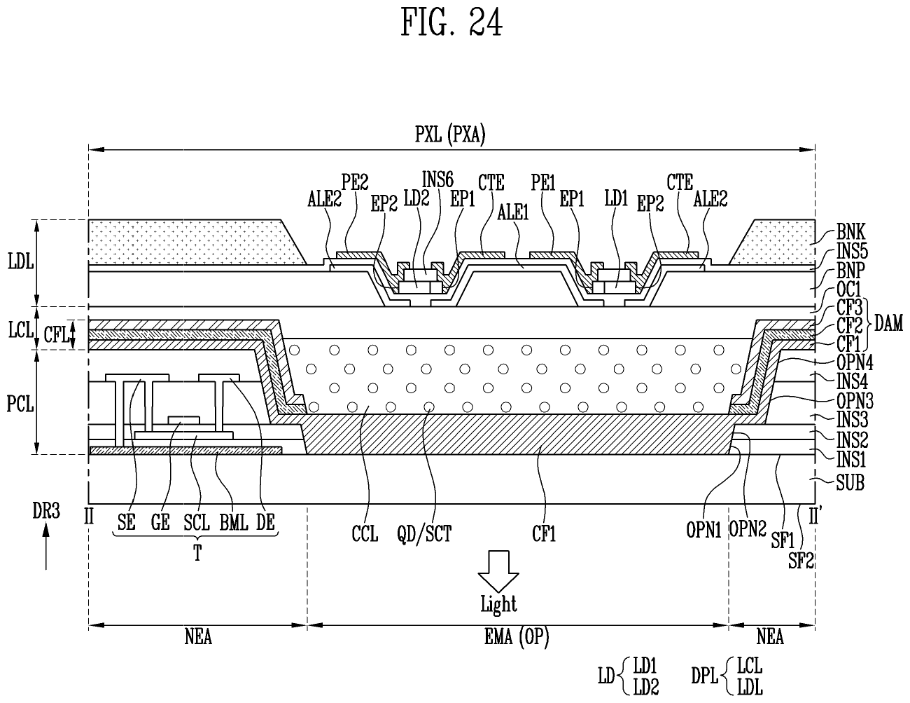

FIG. 12 to FIG. 24 illustrate schematic cross-sectional views taken along the line II-II′ of FIG. 6 for explaining a manufacturing method of a display device according to one or more embodiments.

Hereinafter, a manufacturing method of a display device according to one or more embodiments will be sequentially described with reference to FIG. 12 to FIG. 24.

In one or more embodiments, although manufacturing steps of the display device are described as being performed sequentially according to the cross-sectional views, it is obvious that some steps shown as being continuously performed are concurrently (e.g., simultaneously) performed, the order of respective steps is changed, some steps are omitted, or another step is added between respective steps unless the technical scope of the present disclosure is changed.

In FIG. 12 to FIG. 24, differences from the above-described embodiment will be mainly described in order to avoid duplicate descriptions.

Referring to FIG. 1 to FIG. 12, the pixel circuit layer PCL is formed on the first surface SF1 of the substrate SUB.

The pixel circuit layer PCL may include the transistor T and the first, second, third, and fourth insulating layers INS1, INS2, INS3, and INS4.

The transistor T may be formed on the lower metal pattern BML positioned in the non-emission area NEA.

The first insulating layer INS1 is formed on the lower metal pattern BML to cover the lower metal pattern BML, and may be partially opened to include the first opening OPN1 exposing the first surface SF1 of the substrate SUB in at least the emission area EMA.

The second insulating layer INS2 is formed on the first insulating layer INS1, and may be partially opened to include the second opening OPN2 corresponding to the first opening OPN1 in at least the emission area EMA.

The third insulating layer INS3 is formed on the second insulating layer INS2, and may be partially opened to include the third opening OPN3 exposing the first surface SF1 of the substrate SUB in at least the emission area EMA.

The fourth insulating layer INS4 is formed on the third insulating layer INS3, and may be partially opened to include the fourth opening OPN4 corresponding to the third opening OPN3 in at least the emission area EMA.

Both side surfaces of the third insulating layer INS3 with the third opening OPN3 therebetween and both side surfaces of the fourth insulating layer INS4 with the fourth opening OPN4 therebetween may be positioned outside both side surfaces of the second insulating layer INS2 with the second opening OPN2 therebetween, due to etching conditions during the process of forming the pixel circuit layer PCL.

Both side surfaces of the first insulating layer INS1 with the first opening OPN1 therebetween, both side surfaces of the second insulating layer INS2 with the second opening OPN2 therebetween, both side surfaces of the third insulating layer INS3 with the third opening OPN3 therebetween, and both side surfaces of the fourth insulating layer INS4 with the fourth opening OPN4 therebetween respectively have a side slope inclined in the third direction DR3, but are not limited thereto. In one or more embodiments, both side surfaces of the first insulating layer INS1, both side surfaces of the second insulating layer INS2, both side surfaces of the third insulating layer INS3, and both side surfaces of the fourth insulating layer INS4 may be respectively placed on a planar surface in which an etched surface including a straight line parallel to the third direction DR3 is perpendicular to the first surface SF1 of the substrate SUB.

Both side surfaces of the first insulating layer INS1 with the first opening OPN1 therebetween, both side surfaces of the second insulating layer INS2 with the second opening OPN2 therebetween, both side surfaces of the third insulating layer INS3 with the third opening OPN3 therebetween, and both side surfaces of the fourth insulating layer INS4 with the fourth opening OPN4 therebetween may surround at least the emission area EMA and define a formation position SP1 of the color filter layer CFL to be formed by a subsequent process, respectively.

By the first opening OPN1 of the first insulating layer INS1, the second opening OPN2 of the second insulating layer INS2, the third opening OPN3 of the third insulating layer INS3, and the fourth opening OPN4 of the fourth insulating layer INS4, the first surface SF1 of the substrate SUB may be exposed to the outside in at least the emission area EMA.

Referring to FIG. 1 to FIG. 13, the first color filter CF1 is formed on the pixel circuit layer PCL. The first color filter CF1 may be directly formed on the first surface SF1 of the substrate SUB in at least the emission area EMA, and may be formed on the first, second, third, and fourth insulating layers INS1, INS2, INS3, and INS4 in at least the non-emission area NEA.

The first color filter CF1 may be provided in a form of filling the first opening OPN1 of the first insulating layer INS1 and the second opening OPN2 of the second insulating layer INS2 in at least the non-emission area NEA. In addition, the first color filter CF1 may be formed on both side surfaces of the third insulating layer INS3 with the third opening OPN3 therebetween and both side surfaces of the fourth insulating layer INS4 with the fourth opening OPN4 therebetween in at least the non-emission area NEA, respectively.

Referring to FIG. 1 to FIG. 14, the second color filter CF2 is formed on the first color filter CF1 positioned in at least the non-emission area NEA. The second color filter CF2 may be directly formed on the first surface SF1 of the substrate SUB in at least the emission area EMA of the adjacent pixel PXL.

Referring to FIG. 1 to FIG. 15, the third color filter CF3 is formed on the second color filter CF2 positioned in at least the non-emission area NEA. The third color filter CF3 may be directly formed on the first surface SF1 of the substrate SUB in at least the emission area EMA of another adjacent pixel PXL adjacent to the adjacent pixel PXL.

The first color filter CF1, the second color filter CF2, and the third color filter CF3 positioned to overlap each other in at least the non-emission area EMA may configure a dam structure DAM defining a supply position SP2 of the color conversion layer CCL. The dam structure DAM is positioned on the first, second, third, and fourth insulating layers INS1, INS2, INS3, and INS4 in the non-emission area NEA, and may surround the emission area EMA.

Referring to FIG. 1 to FIG. 16, the color conversion layer CCL in which the color conversion particles QD are dispersed or the light scattering layer in which the light scattering particles SCT are sprayed is formed in a space (or the supply position SP2 of the color conversion layer CCL) surrounded by the dam structure DAM by an inkjet printing method or the like. The space may be the emission area EMA of the pixel PXL.

Referring to FIG. 1 to FIG. 17, the first overcoat layer OC1 is entirely formed in the pixel area PXA.

The first overcoat layer OC1 is configured as an organic insulating layer including an organic material and is positioned on the color conversion layer CCL formed in the emission area EMA and the dam structure DAM formed in the non-emission area NEA, so that it may be used as a planarization layer for alleviating a step due to the color conversion layer CCL and the dam structure DAM.

Referring to FIG. 1 to FIG. 18, the bank pattern BNP is formed on the first overcoat layer OC1.

The bank pattern BNP may include a transparent insulating material.

Referring to FIG. 1 to FIG. 19, the second alignment electrode ALE2, the first alignment electrode ALE1, and another second alignment electrode ALE2 disposed to be spaced from each other are formed on the bank pattern BNP.

Each of the second alignment electrode ALE2, the first alignment electrode ALE1, and another second alignment electrode ALE2 may include a transparent conductive material.

Referring to FIG. 1 to FIG. 20, the fifth insulating layer INS5 is entirely formed in the pixel area PXA.

The fifth insulating layer INS5 may be formed on the second alignment electrode ALE2, the first alignment electrode ALE1, and another second alignment electrode ALE2 in at least the emission area EMA.

The fifth insulating layer INS5 may be partially opened to include the second contact hole CH2 exposing one area of the second alignment electrode ALE2 and the first contact hole CH1 exposing one area of the first alignment electrode ALE1 in at least the non-emission area NEA.

Referring to FIG. 1 to FIG. 21, the bank BNK is formed on the fifth insulating layer INS5 to correspond to at least the non-emission area NEA. The bank BNK may include the opening portion OP corresponding to the emission area EMA. The bank BNK may define the supply position of the light emitting elements LD.

Referring to FIG. 1 to FIG. 22, an electric field is formed between adjacent alignment electrodes ALE by applying a corresponding alignment signal to each of the second alignment electrode ALE2, the first alignment electrode ALE1, and another second alignment electrode ALE2.

Ink including the light emitting elements LD is injected into the pixel area PXA by using an inkjet printing method or the like. For example, at least one or more inkjet nozzles are disposed on the fifth insulating layer INS5 and the bank BNK, and ink mixed with the plurality of light emitting elements LD may be injected into the pixel area PXA through the inkjet nozzles. Self-alignment of the first light emitting elements LD1 may be induced on the fifth insulating layer INS5 between the first alignment electrode ALE1 and another second alignment electrode ALE2, and self-alignment of the second light emitting elements LD2 may be induced on the fifth insulating layer INS5 between the first alignment electrode ALE1 and the second alignment electrode ALE2.

Referring to FIG. 1 to FIG. 23, the sixth insulating layer INS6 exposing the first end portion EP1 and the second end portion EP2 of the corresponding light emitting element LD is formed on the first and second light emitting elements LD1 and LD2.

The sixth insulating layer INS6 may be formed as an inorganic insulating layer suitable for protecting an active layer (refer to “12” of FIG. 1) of each of the first and second light emitting elements LD1 and LD2.

Referring to FIG. 1 to FIG. 24, the first electrode PE1, the second electrode PE2, and the intermediate electrode CTE are formed on the sixth insulating layer INS6.

The first electrode PE1 may be formed on the first end portion EP1 of the first light emitting element LD1, the intermediate electrode CTE may be formed on the second end portion EP2 of the first light emitting element LD1 and the first end portion EP1 of the second light emitting element LD2, respectively, and the second electrode PE2 may be formed on the second end portion EP2 of the second light emitting element LD2.

The first electrode PE1, the second electrode PE2, and the intermediate electrode CTE may be formed in the same process, may be positioned on the same layer, and may include the same material. For example, the first electrode PE1, the second electrode PE2, and the intermediate electrode CTE may be made of an opaque metal, and may be a reflective member that guides (or reflects) light emitted from the first and second light emitting elements LD1 and LD2 to the direction of the second surface SF2 of the substrate SUB.

After the first electrode PE1, the second electrode PE2, and the intermediate electrode CTE are formed, a process of entirely forming the second overcoat layer OC2 in the pixel area PXA may be performed. The second overcoat layer OC2 may be made of a light blocking and/or light absorbing material to block light from being incident from the outside and prevent elements positioned thereunder from being viewed.

According to the display device DD formed through the above-described manufacturing method, by removing a portion of each of the first, second, third, and fourth insulating layers INS1, INS2, INS3, and INS4 included in the pixel circuit layer PCL in at least the emission area EMA, the first surface SF1 of the substrate SUB is exposed, and the first color filter CF1 and the color conversion layer CCL are continuously formed on the exposed first surface SF1 of the substrate SUB, so that the manufacturing efficiency may be improved.

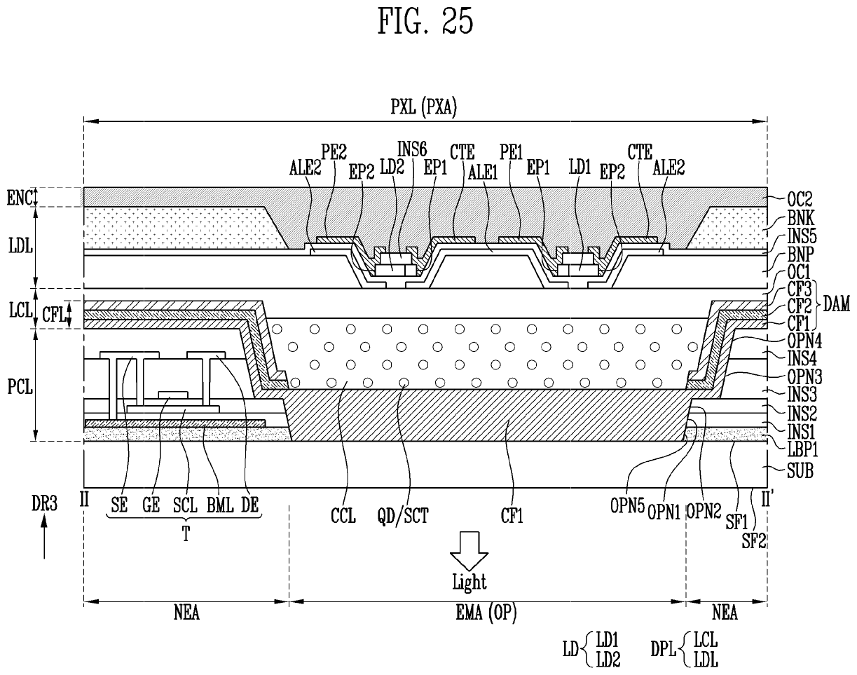

FIG. 25 illustrates the pixel PXL according to one or more embodiments, and illustrates a cross-sectional view taken along the line II-II′ of FIG. 6.

In FIG. 25, differences from the above-described embodiment will be mainly described in order to avoid duplicate descriptions.

Referring to FIG. 1 to FIG. 6 and FIG. 25, the pixel PXL according to the described embodiments may include the pixel circuit layer PCL, the display element layer DPL, and the encapsulation layer ENC disposed on the first surface SF1 of the substrate SUB.

In one or more embodiments, the pixel circuit layer PCL may further include a first light blocking pattern LBP1 respectively positioned between the first surface SF1 of the substrate SUB and the lower metal pattern BML and between the first surface SF1 of the substrate SUB and the first insulating layer INS1.

The first light blocking pattern LBP1 may include a light blocking material that prevents light from leaking between adjacent pixels PXL and prevents light emitted from adjacent pixels PXL from being mixed. For example, the first light blocking pattern LBP1 may include a black matrix. In one or more embodiments, the first light blocking pattern LBP1 may be used as a light blocking member that blocks light that may be incident from the second surface SF2 of the substrate SUB to a circuit element, for example, the transistor T.

The first light blocking pattern LBP1 is positioned only in at least the non-emission area NEA, and may be partially opened to include the fifth opening OPN5 exposing the first surface SF1 of the substrate SUB in at least the non-emission area NEA. The fifth opening OPN5 of the first light blocking pattern LBP1 may correspond to the first opening OPN1 of the first insulating layer INS1, but is not limited thereto.

In one or more embodiments, the first light blocking pattern LBP1 may be a pixel defining layer that finally defines the emission area EMA of the pixel PXL where light passes through the first color filter CF1 to be emitted in the direction of the second surface SF2 of the substrate SUB.

FIG. 26 to FIG. 29 illustrate schematic cross-sectional views taken along the line I-I′ of FIG. 3.

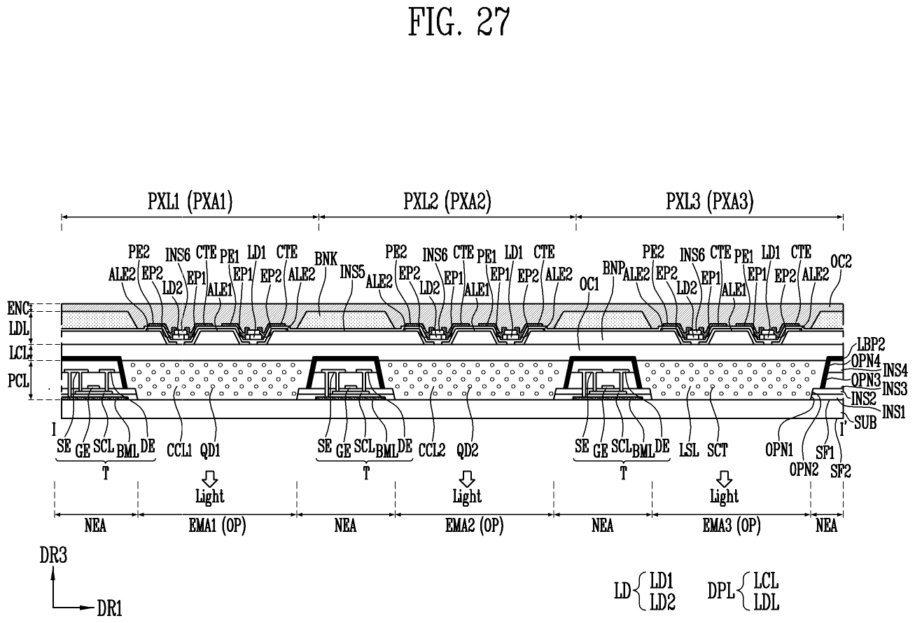

The embodiments of FIG. 27 to FIG. 29 illustrate variations of the embodiment of FIG. 26 in relation to components disposed on the optical layer LCL.

In relation to the embodiments of FIG. 26 to FIG. 29, differences from the above-described embodiment will be mainly described in order to avoid duplicate descriptions.

First, referring to FIG. 3, FIG. 6, and FIG. 26, the first pixel PXL1 (or a first sub-pixel), the second pixel PXL2 (or a second sub-pixel), and the third pixel PXL3 (or a third sub-pixel) may be arranged along the first direction DR1. Each of the first, second, and third pixels PXL1, PXL2, and PXL3 may be the pixel PXL described with reference to FIG. 7 to FIG. 11. The first pixel PXL1 may be a red pixel, the second pixel PXL2 may be a green pixel, and the third pixel PXL3 may be a blue pixel, but are not limited thereto.

The first pixel PXL1 may be positioned in a first pixel area PXA1 provided in the display area DA of the substrate SUB. The first pixel area PXA1 may include a first emission area EMA1 and a non-emission area NEA positioned in at least one side of the first emission area EMA1 (or adjacent to the first emission area EMA1).

The second pixel PXL2 may be positioned in a second pixel area PXA2 provided in the display area DA. The second pixel area PXA2 may include a second emission area EMA2 and a non-emission area NEA positioned in at least one side of the second emission area EMA2 (or adjacent to the second emission area EMA2).

The third pixel PXL3 may be positioned in a third pixel area PXA3 provided in the display area DA. The third pixel area PXA3 may include a third emission area EMA3 and a non-emission area NEA positioned in at least one side of the third emission area EMA3 (or adjacent to the third emission area EMA3).

Each of the first, second, and third pixels PXL1, PXL2, and PXL3 may include the substrate SUB, the pixel circuit layer PCL, the display element layer DPL, and the encapsulation layer ENC. The display element layer DPL of each of the first, second, and third pixels PXL1, PXL2, and PXL3 may include the optical layer LCL and the light emitting element layer LDL.

The optical layer LCL of the first pixel PXL1 may include the color filter layer CFL, a first color conversion layer CCL1, and the first overcoat layer OC1.

The color filter layer CFL may include the second color filter CF2 positioned in at least the first emission area EMA1, and the first color filter CF1, the second color filter CF2, and the third color filter CF3 that are positioned in at least the non-emission area NEA and are sequentially stacked. In one or more embodiments, the second color filter CF2 may be a red color filter, the first color filter CF1 may be a blue color filter, and the third color filter CF3 may be a green color filter.

The first, second, and third color filters CF1, CF2, and CF3 sequentially stacked in at least the non-emission area NEA may be disposed to overlap each other to block light interference between the first, second, and third pixels PXL1, PXL2, and PXL3. In addition, the first, second, and third color filters CF1, CF2, and CF3 sequentially stacked in the non-emission area NEA surround the first emission area EMA1, and may be used as the dam structure DAM defining a supply position of the first color conversion layer CCL1. In addition, the dam structure DAM may be a pixel defining layer that finally defines the first emission area EMA1 of the first pixel PXL1.

The first color conversion layer CCL1 may include first color conversion particles QD1 that convert light of the first color that is emitted from the light emitting elements LD included in the light emitting element layer LDL of the first pixel PXL1 to be reflected in the direction of the second surface SF2 of the substrate SUB by the first and second electrodes PE1 and PE2 and the intermediate electrode CTE into light of a second color (for example, red light). The first color conversion layer CCL1 may include a plurality of first color conversion particles QD1 dispersed in a suitable matrix material (e.g., a predetermined matrix material) such as a base resin. The first color conversion particles QD1 may be red quantum dots. The aforementioned first color conversion layer CCL1 may be disposed on the second color filter CF2 in at least the first emission area EMA1 to correspond to the light emitting elements LD.

The first overcoat layer OC1 may be disposed on the first color conversion layer CCL1 and the dam structure DAM surrounding the first color conversion layer CCL1. The first overcoat layer OC1 may be a planarization layer that alleviates a step caused by the first color conversion layer CCL1 and the dam structure DAM positioned thereunder.

The optical layer LCL of the second pixel PXL2 may include the color filter layer CFL, a second color conversion layer CCL2, and the first overcoat layer OC1.

The color filter layer CFL may include the third color filter CF3 positioned in at least the second emission area EMA2, and the first color filter CF1, the second color filter CF2, and the third color filter CF3 that are positioned in at least the non-emission area NEA and are sequentially stacked. The third color filter CF3 positioned in the second emission area EMA2 may be a green color filter.

The first, second, and third color filters CF1, CF2, and CF3 sequentially stacked in at least the non-emission area NEA may block light interference between the first, second, and third pixels PXL1, PXL2, and PXL3, and may be used as the dam structure DAM that surrounds the second emission area EMA2 and defines a supply position of the second color conversion layer CCL2. In addition, the dam structure DAM may be a pixel defining layer that finally defines the second emission area EMA2 of the second pixel PXL2.

The second color conversion layer CCL2 may include the second color conversion particles QD2 that convert light of the first color that is emitted from the light emitting elements LD included in the light emitting element layer LDL of the second pixel PXL2 to be reflected in the direction of the second surface SF2 of the substrate SUB by the first and second electrodes PE1 and PE2 and the intermediate electrode CTE into light of a second color (for example, green light). The second color conversion layer CCL2 may include a plurality of second color conversion particles QD2 dispersed in a suitable matrix material (e.g., a predetermined matrix material) such as a base resin. The second color conversion particles QD2 may be green quantum dots. The aforementioned second color conversion layer CCL2 may be disposed on the third color filter CF3 in at least the second emission area EMA2 to correspond to the light emitting elements LD.

The first overcoat layer OC1 may be disposed on the second color conversion layer CCL2 and the dam structure DAM surrounding the second color conversion layer CCL2. The first overcoat layer OC1 may be a planarization layer that alleviates a step caused by the second color conversion layer CCL2 and the dam structure DAM positioned thereunder.

The optical layer LCL of the third pixel PXL3 may include the color filter layer CFL, the light scattering layer LSL, and the first overcoat layer OC1.

The color filter layer CFL may include the first color filter CF1 positioned in at least the third emission area EMA3, and the first color filter CF1, the second color filter CF2, and the third color filter CF3 that are positioned in at least the non-emission area NEA and are sequentially stacked. The first color filter CF1 positioned in the third emission area EMA3 may be a blue color filter.

The first, second, and third color filters CF1, CF2, and CF3 sequentially stacked in at least the non-emission area NEA may block light interference between the first, second, and third pixels PXL1, PXL2, and PXL3, and may be used as the dam structure DAM that surrounds the third emission area EMA3 and defines a supply position of the light scattering layer LSL. In addition, the dam structure DAM may be a pixel defining layer that finally defines the third emission area EMA3 of the third pixel PXL3.

The light scattering layer LSL may include the light scattering particles SCT that scatter light of the first color (for example, blue light) that is emitted from the light emitting elements LD included in the light emitting element layer LDL of the third pixel PXL3 to be reflected in the direction of the second surface SF2 of the substrate SUB by the first and second electrodes PE1 and PE2 and the intermediate electrode CTE. The light scattering layer LSL may include a plurality of light scattering particles SCT dispersed in a suitable matrix material (e.g., a predetermined matrix material) such as a base resin. The light scattering layer LSL may include light scattering particles SCT such as silica, but materials included in the light scattering particles SCT are not limited thereto. In one or more embodiments, the light scattering particles SCT may be omitted to provide the light scattering layer LSL made of a transparent polymer. The aforementioned light scattering layer LSL may be disposed on the first color filter CF1 in at least the third emission area EMA3 to correspond to the light emitting elements LD.

The first overcoat layer OC1 may be disposed on the light scattering layer LSL and the dam structure DAM surrounding the light scattering layer LSL. The first overcoat layer OC1 may be a planarization layer that alleviates a step caused by the light scattering layer LSL and the dam structure DAM positioned thereunder.

The first overcoat layer OC1 may be a common layer commonly provided in the first, second, and third pixel areas PXA1, PXA2, and PXA3.

The light emitting element layer LDL of each of the first, second, and third pixels PXL1, PXL2, and PXL3 may be disposed on the above-described first overcoat layer OC1. The light emitting element layer LDL of each of the first, second, and third pixels PXL1, PXL2, and PXL3 may include the bank BNK, the alignment electrodes ALE, the light emitting elements LD, the first and second electrodes PE1 and PE2, and the intermediate electrode CTE.

The encapsulation layer ENC including the second overcoat layer OC2 may be disposed on the light emitting element layer LDL of each of the first, second, and third pixels PXL1, PXL2, and PXL3.

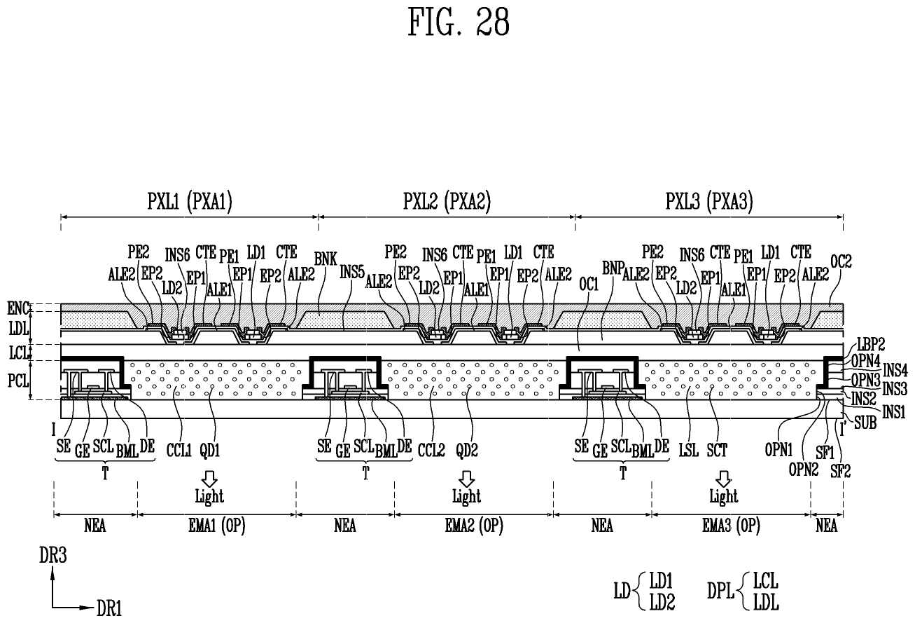

Referring to FIG. 3, FIG. 6, FIG. 27, and FIG. 28, the light emitting element layer LDL of each of the first, second, and third pixels PXL1, PXL2, and PXL3 may include the corresponding color conversion layer or light scattering layer LSL, a second light blocking pattern LBP2, and the first overcoat layer OC1.

The optical layer LCL of the first pixel PXL1 may include the first color conversion layer CCL1 positioned directly on the first surface SF1 of the substrate SUB in at least the first emission area EMA1, the second light blocking pattern LBP2 positioned in the non-emission area NEA adjacent to the first emission area EMA1, and the first overcoat layer OC1.

The optical layer LCL of the second pixel PXL2 may include the second color conversion layer CCL2 positioned directly on the first surface SF1 of the substrate SUB in at least the second emission area EMA2, the second light blocking pattern LBP2 positioned in the non-emission area NEA adjacent to the second emission area EMA2, and the first overcoat layer OC1.

The optical layer LCL of the third pixel PXL3 may include the light scattering layer LSL positioned directly on the first surface SF1 of the substrate SUB in at least the third emission area EMA3, the second light blocking pattern LBP2 positioned in the non-emission area NEA adjacent to the third emission area EMA3, and the first overcoat layer OC1.

The second light blocking pattern LBP2 is disposed on the third and fourth insulating layers INS3 and INS4 of the pixel circuit layer PCL in the non-emission area NEA, and may prevent light emitted from the first, second, and third pixels PXL1, PXL2, and PXL3 from being mixed. The second light blocking pattern LBP2 may include a black matrix, but is not limited thereto. In one or more embodiments, the second light blocking pattern LBP2 surrounds the first, second, and third emission areas EMA1, EMA2, and EMA3, respectively, and may define a supply position of each of the first color conversion layer CCL1, the second color conversion layer CCL2, and the light scattering layer LSL. In addition, the second light blocking pattern LBP2 may be a structure that finally defines each of the first, second, and third emission areas EMA1, EMA2, and EMA3.

The second light blocking pattern LBP2 may have a profile corresponding to profiles of the third and fourth insulating layers INS3 and INS4 positioned thereunder. For example, as shown in FIG. 27, when both side surfaces of the third insulating layer INS3 with the third opening OPN3 therebetween and both side surfaces of the fourth insulating layer INS4 with the fourth opening OPN4 therebetween respectively have a side slope inclined in the third direction DR3, the second light blocking pattern LBP2 may have a side slope corresponding to the side slope. However, the present disclosure is not limited thereto. In one or more embodiments, as shown in FIG. 28, when both side surfaces of the third insulating layer INS3 with the third opening OPN3 therebetween and both side surfaces of the fourth insulating layer INS4 with the fourth opening OPN4 therebetween include straight line parallel to the third direction DR3, the second light blocking pattern LBP2 may have a side surface placed on a planar surface that is perpendicular to the first surface SF1 of the substrate SUB. In one or more embodiments, the second light blocking pattern LBP2 may be disposed on the upper surface of the second insulating layer INS2.

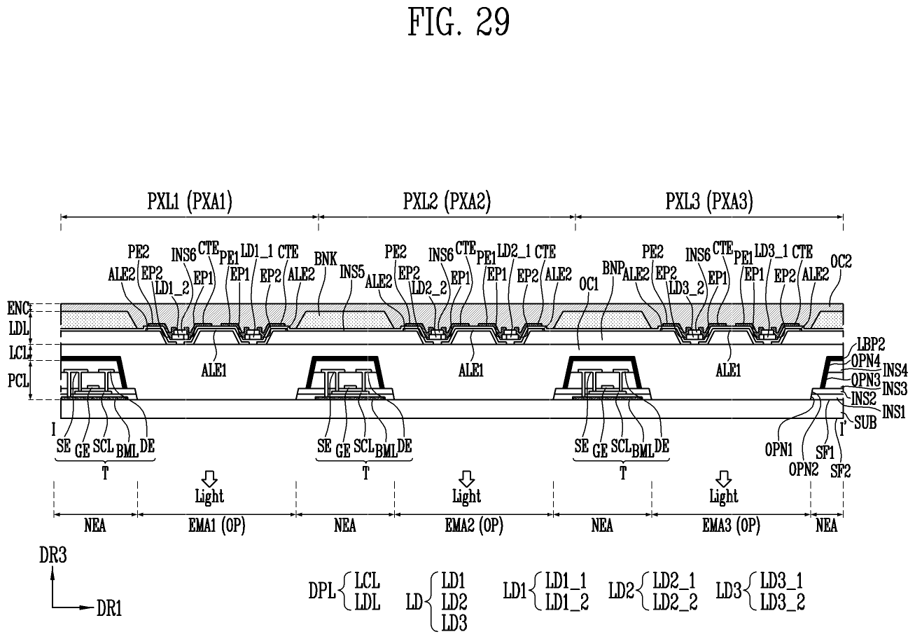

Referring to FIG. 3, FIG. 6, and FIG. 29, the light emitting element layer LDL of each of the first, second, and third pixels PXL1, PXL2, and PXL3 may include the second light blocking pattern LBP2 and the first overcoat layer OC1.

The optical layer LCL of the first pixel PXL1 may include the second light blocking pattern LBP2 positioned in at least the non-emission area NEA, and the first overcoat layer OC1 disposed on the first surface SF1 of the substrate SUB in at least the first emission area EMA1 and disposed on the second light blocking pattern LBP2. The light emitting element layer LDL may be disposed on the first overcoat layer OC1.

The optical layer LCL of the second pixel PXL2 may include the second light blocking pattern LBP2 positioned in at least the non-emission area NEA, and the first overcoat layer OC1 disposed on the first surface SF1 of the substrate SUB in at least the second emission area EMA2 and disposed on the second light blocking pattern LBP2. The light emitting element layer LDL may be disposed on the first overcoat layer OC1.

The optical layer LCL of the third pixel PXL3 may include the second light blocking pattern LBP2 positioned in at least the non-emission area NEA, and the first overcoat layer OC1 disposed on the first surface SF1 of the substrate SUB in at least the third emission area EMA3 and disposed on the second light blocking pattern LBP2. The light emitting element layer LDL may be disposed on the first overcoat layer OC1.

The light emitting element layer LDL of the first pixel PXL1 may include the first and second aligned electrodes ALE1 and ALE2, the first light emitting element LD1, the first and second electrodes PE1 and PE2, and the intermediate electrode CTE. The first light emitting element LD1 may include a (1-1)-th light emitting element LD1_1 and a (1-2)-th light emitting element LD1_2. A first end portion EP1 of the (1-1)-th light emitting element LD1_1 may be electrically connected to the first electrode PE1, and a second end portion EP2 of the (1-1)-th light emitting element LD1_1 may be electrically connected to the intermediate electrode CTE. A first end portion EP1 of the (1-2)-th light emitting element LD1_2 may be electrically connected to the intermediate electrode CTE, and a second end portion EP2 of the (1-2)-th light emitting element LD1_2 may be electrically connected to the second electrode PE2. In the described embodiments, the first light emitting element LD1 including the (1-1)-th light emitting element LD1_1 and the (1-2)-th light emitting element LD1_2 may be a red light emitting element emitting red light. The red light emitted from the first light emitting element LD1 may be reflected by the first and second electrodes PE1 and PE2 and the intermediate electrode CTE to be directed in the direction of the second surface SF2 of the substrate SUB. In this case, the second light blocking pattern LBP2 positioned on the optical layer LCL may prevent the red light directed in the direction of the second surface SF2 of the substrate SUB from being mixed with light that is emitted from the pixel adjacent thereto, for example, the second light emitting element LD2 of the second pixel PXL2 and directed in the direction of the second surface SF2 of the substrate SUB.

The light emitting element layer LDL of the second pixel PXL2 may include the first and second alignment electrodes ALE1 and ALE2, the second light emitting element LD2, the first and second electrodes PE1 and PE2, and the intermediate electrode CTE. The second light emitting element LD2 may include a (2-1)-th light emitting element LD2_1 and a (2-2)-th light emitting element LD2_2. A first end portion EP1 of the (2-1)-th light emitting element LD2_1 may be electrically connected to the first electrode PE1, and a second end portion EP2 of the (2-1)-th light emitting element LD2_1 may be electrically connected to the intermediate electrode CTE. A first end portion EP1 of the (2-2)-th light emitting element LD2_2 may be electrically connected to the intermediate electrode CTE, and a second end portion EP2 of the (2-2)-th light emitting element LD2_2 may be electrically connected to the second electrode PE2. In one or more embodiments, the second light emitting element LD2 including the (2-1)-th light emitting element LD2_1 and the (2-2)-th light emitting element LD2_2 may be a light emitting element emitting green light. The green light emitted from the second light emitting element LD2 may be reflected by the first and second electrodes PE1 and PE2 and the intermediate electrode CTE to be directed in the direction of the second surface SF2 of the substrate SUB. In this case, the second light blocking pattern LBP2 positioned on the optical layer LCL may prevent the green light directed in the direction of the second surface SF2 of the substrate SUB from being mixed with red light that is emitted from the pixel adjacent thereto, for example, the first light emitting element LD1 of the first pixel PXL1 and directed in the direction of the second surface SF2 of the substrate SUB and light (for example, blue light) that is emitted from the third light emitting element LD3 of the third pixel PXL3 and directed in the direction of the second surface SF2 of the substrate SUB.

The light emitting element layer LDL of the third pixel PXL3 may include the first and second aligned electrodes ALE1 and ALE2, the third light emitting element LD3, the first and second electrodes PE1 and PE2, and the intermediate electrode CTE. The third light emitting element LD3 may include a (3-1)-th light emitting element LD3_1 and a (3-2)-th light emitting element LD3_2. A first end portion EP1 of the (3-1)-th light emitting element LD3_1 may be electrically connected to the first electrode PE1, and a second end portion EP2 of the (3-1)-th light emitting element LD3_1 may be electrically connected to the intermediate electrode CTE. A first end portion EP1 of the (3-2)-th light emitting element LD3_2 may be electrically connected to the intermediate electrode CTE, and a second end portion EP2 of the (3-2)-th light emitting element LD3_2 may be electrically connected to the second electrode PE2. In one or more embodiments, the third light emitting element LD3 including the (3-1)-th light emitting element LD3_1 and the (3-2)-th light emitting element LD3_2 may be a light emitting element emitting blue light. The blue light emitted from the third light emitting element LD3 may be reflected by the first and second electrodes PE1 and PE2 and the intermediate electrode CTE to be directed in the direction of the second surface SF2 of the substrate SUB. In this case, the second light blocking pattern LBP2 positioned on the optical layer LCL may prevent the blue light directed in the direction of the second surface SF2 of the substrate SUB from being mixed with green light that is emitted from the pixel adjacent thereto, for example, the second light emitting element LD2 of the second pixel PXL2 and directed in the direction of the second surface SF2 of the substrate SUB.

As described above, when the first light emitting element LD1 emits red light, the second light emitting element LD2 emits green light, and the third light emitting element LD3 emits blue light, a color conversion layer (refer to “CCL” in FIG. 7) that converts light emitted from the light emitting elements LD into light of a specific color, and a color filter layer that selectively transmits light emitted from the color conversion layer CCL (refer to “CFL” in FIG. 7) may be omitted.

While the present disclosure has been shown and described with reference to certain embodiments thereof, it will be understood by those skilled in the art that various changes in forms and details may be made therein without departing from the spirit and scope of the present disclosure as defined by the appended claims and their equivalents.

Therefore, the technical scope of the present disclosure may be determined by the technical scope of the accompanying claims and their equivalents.

What is claimed is:

1. A display device comprising:
a substrate including a display area, the substrate comprising a first surface and a second surface opposite each other; and
a plurality of pixels in the display area, the plurality of pixels including an emission area and a non-emission area,
wherein each of the plurality of pixels comprises:
a pixel circuit layer comprising one or more transistors on the first surface of the substrate in the non-emission area, and a first insulating layer, a second insulating layer, a third insulating layer, and a fourth insulating layer that are sequentially stacked on the first surface of the substrate and respectively include an opening exposing the first surface of the substrate in the emission area;
an optical layer on the pixel circuit layer; and
a light emitting element layer on the optical layer and comprising a light emitting element that is electrically connected to the one or more transistors to emit light,
wherein the optical layer fills the opening of each of the first to fourth insulating layers in at least the emission area.

2. The display device of claim 1, wherein:
each of the plurality of pixels further comprises a second overcoat layer on the light emitting element layer, and
the second overcoat layer comprises a material configured to block and absorb external light.

3. The display device of claim 2, wherein:
the first insulating layer includes a first opening exposing the first surface of the substrate in the emission area,
the second insulating layer includes a second opening corresponding to the first opening in the emission area,
the third insulating layer includes a third opening exposing the first surface of the substrate in the emission area, and
the fourth insulating layer includes a fourth opening corresponding to the third opening in the emission area.

4. The display device of claim 3, wherein the optical layer comprises:
a color conversion layer in the emission area to correspond to the light emitting element and comprising color conversion particles;
a color filter layer between the color conversion layer and the first surface of the substrate in at least the emission area, and configured to selectively transmit light emitted from the color conversion layer to the second surface of the substrate; and
a first overcoat layer between the color filter layer and the light emitting element layer,
wherein the first overcoat layer is on the optical layer covering the optical layer, the first overcoat layer comprising an organic insulating layer having a flat surface.

5. The display device of claim 4, wherein the color filter layer comprises:
a first color filter directly on the first surface of the substrate exposed by the first to fourth openings in at least the emission area and on the fourth insulating layer in at least the non-emission area;
a second color filter on the first color filter in at least the non-emission area; and
a third color filter on the second color filter in at least the non-emission area.

6. The display device of claim 5, wherein:
the color conversion layer is on the first color filter in at least the emission area, and is surrounded by the first to third color filters sequentially stacked in the non-emission area.

7. The display device of claim 6, wherein:
the first color filter comprises a blue color filter,
the second color filter comprises a red color filter, and
the third color filter comprises a green color filter.

8. The display device of claim 4, wherein the light emitting element layer comprises:
a first alignment electrode and a second alignment electrode on the first overcoat layer and spaced from each other;
a fifth insulating layer on the first and second aligned electrodes;
a bank in the non-emission area and including an opening portion corresponding to the emission area;
the light emitting element in at least the emission area and located on the fifth insulating layer between the first alignment electrode and the second alignment electrode;
a sixth insulating layer on the light emitting element and exposing a first end portion and a second end portion of the light emitting element; and
a first electrode and a second electrode in at least the emission area, spaced from each other on the sixth insulating layer, and electrically connected to the light emitting element.

9. The display device of claim 8, wherein:
the first and second alignment electrodes comprise a transparent conductive material, and
the first and second electrodes comprise an opaque conductive material.

10. The display device of claim 8, wherein the pixel circuit layer further comprises:
a lower metal pattern between the first insulating layer and the first surface of the substrate in at least the non-emission area;
a first power line configured to receive a voltage of a first driving power source; and
a second power line configured to receive a voltage of a second driving power source different from the first driving power source,
wherein the lower metal pattern is electrically connected to the one or more transistors.

11. The display device of claim 10, wherein:
the lower metal pattern is a light blocking member blocking external light that is incident from the second surface of the substrate to the one or more transistors.

12. The display device of claim 11, wherein:
in at least the non-emission area, the first alignment electrode is electrically connected to the first electrode through a first contact hole penetrating the fifth insulating layer;
in at least the non-emission area, the second alignment electrode is electrically connected to the second electrode through a second contact hole penetrating the fifth insulating layer; and
in at least the non-emission area, the second alignment electrode is electrically connected to the second power line through a via hole penetrating the first overcoat layer, the color filter layer, and the fourth insulating layer.

13. The display device of claim 10, wherein:
the pixel circuit layer further comprises a first light blocking pattern between the first surface of the substrate and the lower metal pattern in at least the non-emission area.

14. The display device of claim 1, wherein:
the plurality of pixels is located on the first surface of the substrate, and comprises a first pixel including a first emission area, a second pixel including a second emission area, and a third pixel including a third emission area; and
each of the first to third pixels comprises the pixel circuit layer, the optical layer, and the light emitting element layer.

15. The display device of claim 14, wherein the optical layer of the first pixel comprises:
a first color conversion layer in the first emission area and comprising first color conversion particles; and
a second color filter between the first color conversion layer and the first surface of the substrate in the first emission area,
wherein the optical layer of the second pixel comprises:
a second color conversion layer in the second emission area and comprising second color conversion particles; and
a third color filter between the second color conversion layer and the first surface of the substrate in the second emission area,
wherein the optical layer of the third pixel comprises:
a light scattering layer in the third emission area and comprising light scattering particles; and
a first color filter in the third emission area and located between the light scattering layer and the first surface of the substrate,
wherein the first color filter is a blue color filter, the second color filter is a red color filter, and the third color filter is a green color filter.

16. The display device of claim 15, wherein:
each of the first color conversion layer, the second color conversion layer, and the light scattering layer is surrounded by the first to third color filters sequentially stacked in the non-emission area.

17. The display device of claim 14, wherein the optical layer of the first pixel comprises:
a first color conversion layer in the first emission area and comprising first color conversion particles; and
a second light blocking pattern in a corresponding non-emission area adjacent to the first emission area and surrounding at least a portion of the first color conversion layer,
wherein the optical layer of the second pixel comprises:
a second color conversion layer in the second emission area and comprising second color conversion particles; and
the second light blocking pattern in a corresponding non-emission area adjacent to the second emission area and surrounding at least a portion of the second color conversion layer, and
wherein the optical layer of the third pixel comprises:
a light scattering layer in the third emission area and comprising light scattering particles; and
the second light blocking pattern in a corresponding non-emission area adjacent to the third emission area and surrounding at least a portion of the light scattering layer.

18. The display device of claim 17, wherein:
the first color conversion layer is on the first surface of the substrate in at least the first emission area;
the second color conversion layer is on the first surface of the substrate in at least the second emission area; and
the light scattering layer is on the first surface of the substrate in at least the third emission area.

19. A display device comprising:
a substrate including a display area and a non-display area, and a first surface and a second surface opposite each other; and
a first pixel including a first emission area, a second pixel including a second emission area, and a third pixel including a third emission area, the first to third pixels being located on the first surface of the substrate,
wherein each of the first to third pixels comprises:
one or more transistors on the first surface of the substrate to correspond to a non-emission area between adjacent emission areas from among the first to third emission areas;
a first insulating layer, a second insulating layer, a third insulating layer, and a fourth insulating layer, each of the first to fourth insulating layers including an opening exposing the first surface of the substrate in each of the first to third emission areas;
a light blocking pattern on the third and fourth insulating layers in the non-emission area;
a first overcoat layer on the first surface of the substrate in each of the first to third emission areas and on the light blocking pattern in at least the non-emission area;
a light emitting element layer on the first overcoat layer and comprising a light emitting element electrically connected to the one or more transistors; and
a second overcoat layer on the light emitting element layer,
wherein the light emitting element of the first pixel is configured to emit red light, the light emitting element of the second pixel is configured to emit green light, and the light emitting element of the third pixel is configured to emit blue light.

20. A manufacturing method of a display device, comprising:
preparing a substrate including a display area, and a first surface and a second surface opposite each other; and
forming a plurality of pixels, each of the plurality of pixels including an emission area and a non-emission area on the first surface of the substrate,
wherein the forming of the plurality of pixels comprises:
forming a pixel circuit layer comprising one or more transistors on the first surface of the substrate corresponding to the non-emission area, and forming a first insulating layer, a second insulating layer, a third insulating layer, and a fourth insulating layer that are sequentially stacked on the first surface of the substrate and respectively include an opening exposing the first surface of the substrate in the emission area;
forming an optical layer on the pixel circuit layer; and
forming a light emitting element layer including a light emitting element emitting light on the optical layer,
wherein the optical layer fills the opening of each of the first to fourth insulating layers in at least the emission area.
